(19) United States
(12) Patent Application Publication
(10) Pub. No.: US 2025/0072241 A1
(43) Pub. Date: Feb. 27, 2025

(54) PAD STRUCTURE OF DISPLAY DEVICE AND METHOD OF PROVIDING THE SAME

(71) Applicant: Samsung Display Co., Ltd., Yongin-si (KR)

(72) Inventors: YOUNGMIN AHN, Yongin-si (KR); DAEHWAN JANG, Yongin-si (KR); HANBUM KWON, Yongin-si (KR); EUNBYUL KIM, Yongin-si (KR)

(21) Appl. No.: 18/779,194

(22) Filed: Jul. 22, 2024

(30) Foreign Application Priority Data
Aug. 22, 2023 (KR) 10-2023-0109443

(51) Int. Cl. H10K 59/131; H10K 59/12

(52) U.S. Cl. CPC H10K 59/131; H10K 59/1201

(57) ABSTRACT

A display device includes a display module including a signal line electrically connected to a pixel and defining an end portion furthest from the pixel, and a signal pad electrically connected to the signal line and to which an electrical signal is provided from an electronic component external to the display module. The signal pad includes a first conductive pattern at which the signal pad is electrically connected to the end portion of the signal line, a second conductive pattern facing the first conductive pattern and electrically connected to the first conductive pattern, an insulation pattern between the first and second conductive patterns, and a protruding conductive pattern at which the signal pad is electrically connected to the electronic component, the protruding conductive pattern protruding from the second conductive pattern and overlapping the insulation pattern.

This application claims priority to Korean Patent Application No. 10-2023-0109443, filed on Aug. 22, 2023, and all the benefits accruing therefrom under 35 U.S.C. § 119, the entire contents of which are hereby incorporated by reference.

### BACKGROUND

### (1) Field

The present disclosure herein relates to a display device and a method of manufacturing (or providing) the same. More particularly, the present disclosure herein relates to a pad region of the display device.

### (2) Description of the Related Art

A display device includes a display region as an active region which is activated in response to electrical signals. The display device may detect an input applied from the outside (e.g., outside of the display device), and at the same time, display various images to provide information to outside the display device, such as to a user, through the display region.

The display device includes a display panel and a circuit board. The display panel may be electrically connected to a main board through the circuit board. A driving chip may be mounted on the display panel.

### SUMMARY

The present disclosure provides a display device with improved bonding reliability, and a method of manufacturing (or providing) the display device.

An embodiment of the invention provides a display device including a display module, where the display module includes a pixel, a signal line electrically connected to the pixel and defining an end portion furthest from the pixel, and a signal pad electrically connected to the signal line and to which an electrical signal is provided from an electronic component external to the display module, and the signal pad includes a first conductive pattern at which the signal pad is electrically connected to the end portion of the signal line, a second conductive pattern facing the first conductive pattern and electrically connected to the first conductive pattern, an insulation pattern between the first conductive pattern and the second conductive pattern which face each other, and a protruding (conductive) pattern at which the signal pad is electrically connected to the electronic component, and the protruding conductive pattern protrudes from the second conductive pattern and a overlaps the insulation pattern on a plane (e.g., in a plan view).

In an embodiment, the protruding conductive pattern may include metal, and the insulation pattern may include polymer.

In an embodiment, the protruding conductive pattern may include copper or silver.

In an embodiment, the second conductive pattern may include a protruding portion extended along the insulation pattern and protruding from the first conductive pattern, and the protruding conductive pattern may protrude from the protruding portion of the second conductive pattern.

In an embodiment, the first conductive pattern may extend further than a side surface of the insulation pattern to define an upper surface of the first conductive pattern which is exposed outside of the insulation pattern, and the second conductive pattern may further comprise the protruding portion in contact with the side surface and an upper surface of the insulation pattern, and an extended portion which extends from the protruding portion and further from the insulation pattern, the extended portion contacting the upper surface of the first conductive pattern.

In an embodiment, an entirety of the protruding conductive pattern of the signal pad is may be overlapped by the insulation pattern.

In an embodiment, each of the protruding conductive pattern and the second conductive pattern may have a side surface, and the side surface of the protruding conductive pattern may be substantially aligned with the side surface of the second conductive pattern.

In an embodiment, the protruding conductive pattern may comprise one of a trapezoid cross-sectional shape, a reversed trapezoid cross-sectional shape, and a rectilinear cross-sectional shape.

In an embodiment, the second conductive pattern may include a first layer, a second layer, and a third layer in a direction from the insulation pattern to the protruding conductive pattern, the second layer which is thicker may have higher conductivity than that of each of the first and third layers, and a portion of the second layer may be exposed outside of the third layer to be in contact with the protruding conductive pattern, and the protruding conductive pattern may contact the portion of the second layer which is exposed outside of the third layer.

In an embodiment, the second conductive pattern may further include an oxide film stacked in sequence in the direction from the insulation pattern to the protruding conductive pattern, and the portion of the second layer may be exposed outside of both the oxide film and the third layer, and the protruding conductive pattern may contact the portion of the second layer which is exposed outside of both the oxide film and the third layer.

In an embodiment, within the signal pad, the protruding conductive pattern may be provided in plural including protruding conductive patterns spaced apart from each other along the insulation pattern.

In an embodiment, within the signal pad, the insulation pattern and the protruding conductive pattern may be each provided in plural, and the protruding conductive patterns may respectively overlap the insulation patterns.

In an embodiment, the display module may further include a pad insulation layer between the first conductive pattern of the signal pad and the end portion of the signal line, within the signal pad, a contact hole may be defined in the pad insulation layer which exposes the end portion of the signal line to outside the pad insulation layer and be spaced apart from the insulation pattern in a direction along the signal pad, and the first conductive pattern may contact the end portion of the signal line through the contact hole which is defined in the pad insulation layer.

In an embodiment, within the signal pad, the insulation pattern and the contact hole may be each provided in plural, and the insulation patterns may be between adjacent contact holes among the contact holes.

In an embodiment, the pixel may include a light-emitting element, a transistor electrically connected to the light-emitting element, and including a semiconductor pattern and a gate overlapping the semiconductor pattern, an upper electrode on the gate of the transistor, and connection electrodes electrically connected to the transistor, and on different layers, the end portion of the signal line may be in a same layer as the gate of the transistor or the upper electrode, the first conductive pattern may be in a same layer as that of a first connection electrode among the connection electrodes, and the second conductive pattern may be in a same layer as a second connection electrode different from the first connection electrode among the connection electrodes.

In an embodiment, the electronic component may include a bump electrode at which the electronic component is electrically connected to the signal pad of the display module, and an adhesive layer which is between the display module and the electronic component, may bond the display module to the electronic component and within which the protruding conductive pattern may be in contact with the bump electrode to electrically connect the electronic component to the display module.

In an embodiment of the invention, a method of manufacturing or providing a display device includes providing a preliminary signal pad including a first conductive pattern connected to a signal line of a display module of the display device, a second conductive pattern on the first conductive pattern, and an insulation pattern between the first conductive pattern and the second conductive pattern, and forming (or providing) a protruding conductive pattern on the preliminary signal pad to form the signal pad of the display module at which the display module of the display device is connected to an electronic component of the display device, and the forming of the protruding conductive pattern on the preliminary signal pad may comprise a reverse offset printing process.

In an embodiment, the providing of the protruding conductive pattern may further comprise providing a layer of metal ink including a solvent and metal nanoparticles, onto a blanket movable relative to the preliminary signal pad.

In an embodiment, the providing of the protruding conductive pattern may further comprise after the providing of the layer of the metal ink, transferring a portion of the layer of the metal ink from the blanket to a carrier, which provides a print pattern corresponding to the remaining portion of the layer of the metal ink which is on the blanket, transferring the print pattern from the blanket onto the second conductive pattern of the preliminary signal pad, the print pattern overlapping the insulation pattern of the preliminary signal pad, and sintering the print pattern which is on the second conductive pattern and overlapping the insulation pattern of the preliminary signal pad, to form the protruding conductive pattern of the signal pad.

In an embodiment, the providing of the protruding conductive pattern may further comprise after the providing of the layer of the metal ink, transferring a portion of the layer of the metal ink from the blanket, directly to the second conductive pattern of the preliminary signal pad, which provides a print pattern of the layer of the metal ink which is on the preliminary signal pad, the print pattern overlapping the insulation pattern of the preliminary signal pad, and sintering the print pattern which is on the second conductive pattern and overlapping the insulation pattern of the preliminary signal pad, to form the protruding conductive pattern of the signal pad.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain the invention. In the drawings:

FIG. 1 is a perspective view of a display device according to an embodiment of the invention;

FIGS. 2A and 2B are exploded perspective views of a display device according to an embodiment of the invention;

FIG. 3 is a cross-sectional view of a display module according to an embodiment of the invention;

FIG. 4 is a plan view of a display panel according to an embodiment of the invention;

FIG. 5 is a cross-sectional view of a pixel according to an embodiment of the invention;

FIG. 6 is an enlarged exploded perspective view illustrating a pad region of a display device according to an embodiment of the invention;

FIG. 7A is a plan view schematically illustrating a pad region according to an embodiment of the invention;

FIGS. 7B and 7C are cross-sectional views corresponding to A-A′ and B-B′ of FIG. 7A, respectively;

FIGS. 8A to 8C are cross-sectional views corresponding to B-B′ of FIG. 7A;

FIG. 9A is a cross-sectional view corresponding to B-B′ of FIG. 7A and illustrating a bonding structure of a display device according to an embodiment of the invention;

FIG. 9B is an enlarged cross-sectional view of region XX′ of FIG. 9A;

FIGS. 10A to 10D are plan views schematically illustrating a pad region according to an embodiment of the invention;

FIGS. 11A and 11B are plan views schematically illustrating a pad region according to an embodiment of the invention;

FIGS. 12A to 12G are cross-sectional views illustrating a method of manufacturing (or providing) of a display device according to an embodiment of the invention; and

FIGS. 13A and 13B are cross-sectional views illustrating a method of manufacturing (or providing) of a display device according to an embodiment of the invention.

### DETAILED DESCRIPTION

In this specification, it will be understood that when an element (or a region, a layer, a portion, or the like) is referred to as being related to another element such as being “on”, “connected to” or “coupled to” another element, it may be directly disposed on, connected or coupled to the other element, or intervening elements may be disposed therebetween. In contrast, when an element (or a region, a layer, a portion, or the like) is referred to as being related to another element such as being “directly on”, “directly connected to” or “directly coupled to” another element, no intervening element is therebetween.

Like reference numerals or symbols refer to like elements throughout. Within the Figures and the text of the disclosure, a reference number indicating a singular form of an element may also be used to reference a plurality of the singular element. In the drawings, the thickness, the ratio, and the size of the element are exaggerated for effective description of the technical contents.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the invention. Similarly, a second element, component, region, layer or section may be termed a first element, component, region, layer or section.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “comprises,” “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the invention are described with reference to the accompanying drawings.

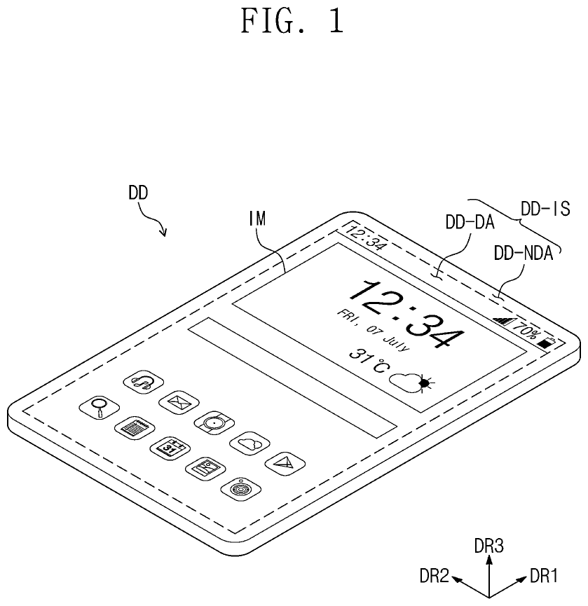

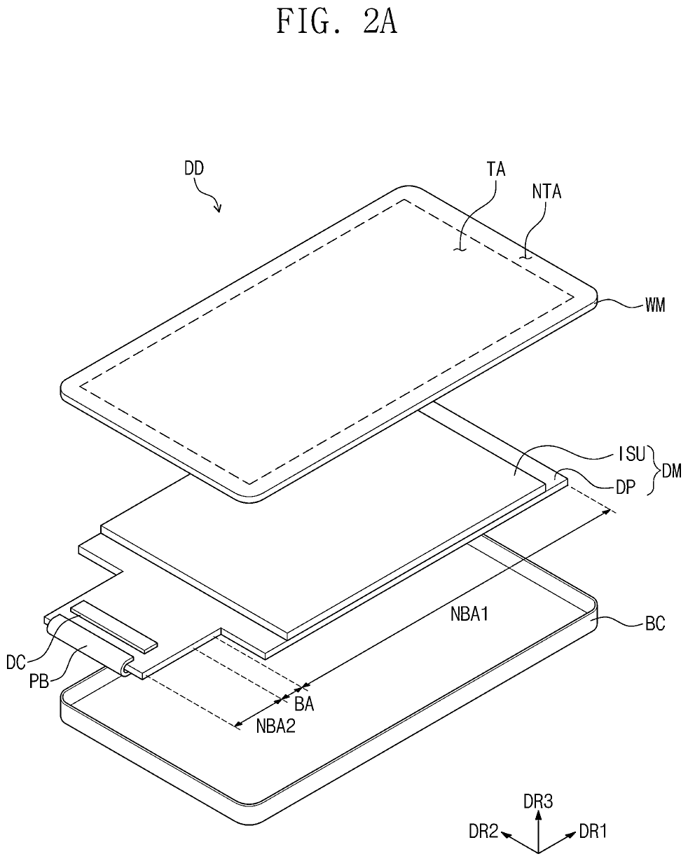

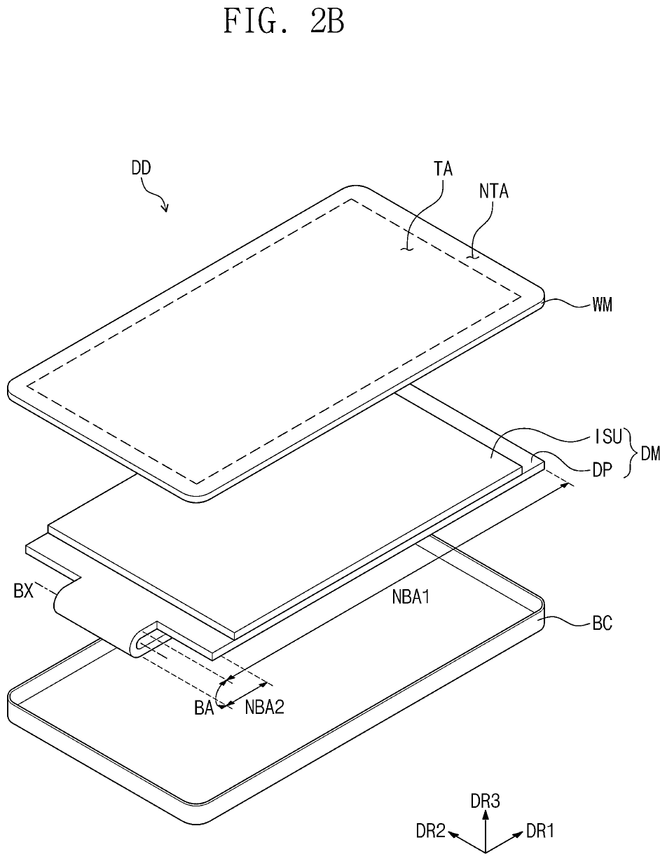

FIG. 1 is a perspective view of a display device DD according to an embodiment of the invention. FIGS. 2A and 2B are exploded perspective views of a display device DD according to an embodiment of the invention.

FIG. 2B exemplarily illustrates that a bending region BA, illustrated in FIG. 2A, is in a bent state.

Referring to FIG. 1, in this specification, a mobile phone is illustrated as an example of the display device DD. The display device DD according to an embodiment of the invention may be applied not only to a large electronic apparatus such as a television and monitor, but also a small to medium-sized electronic apparatus such as a tablet computer, a car navigation system, a game console, and a smart watch.

The display device DD may have a rectangular shape, on a plane (e.g., a planar shape along a DR1-DR2 plane), having long sides extending in a first direction DR1 and short sides extending in a second direction DR2 which crosses the first direction DR1. However, an embodiment of the invention is not limited thereto, and the display device DD may have various shapes such as circle and polygonal shapes on a plane.

Hereinafter, a direction intersecting a plane defined by the first direction DR1 and the second direction DR2 crossing each other is defined as a third direction DR3. The third direction DR3 may be substantially perpendicular to the plane, without being limited thereto. In this specification, “when viewed on a plane” may refer to a state when viewed from (or along) the third direction DR3. A thickness of the display device DD and various components or layers thereof may be defined along the third direction DR3 (e.g., a thickness direction).

The display device DD may be rigid or flexible. “To be flexible” may mean to have bending characteristics, and may include from a completely folded structure to a structure bendable at the level of a few nanometers. For example, a flexible display device DD may include a curved display device, a rollable display device, or a foldable display device. Various components or layers of the display device DD may be curvable, rollable, foldable, bendable, etc. together with each other.

The display device DD may display an image IM through a display surface DD-IS. Icon images are illustrated as an example of the image IM. The display surface DD-IS may be parallel to a plane defined by the first direction DR1 and the second direction DR2.

The display surface DD-IS may include a display region DD-DA in which the image IM is displayed, and a non-display region DD-NDA which is adjacent to the display region DD-DA. The non-display region DD-NDA may be a region or planar area in which the image IM is not displayed. However, an embodiment of the invention is not limited thereto, and the non-display region DD-NDA may be adjacent to any one side of the display region DD-DA while being excluded from another side thereof, or entirely omitted.

Referring to FIGS. 2A and 2B, a display device DD may include a window WM, a display module DM, and an accommodation member BC.

The window WM may be disposed above the display module DM, and may transmit an image IM provided from the display module DM to outside (e.g., outside of the display device DD, such as to a user). The window WM may include a transmission region TA and a non-transmission region NTA. The transmission region TA may overlap the display region DD-DA illustrated in FIG. 1, and have a shape (e.g., a planar shape) corresponding to the display region DD-DA. Although not illustrated in the drawing, the window WM may include a base layer, and functional layers disposed on the base layer. The functional layers may include a protection layer, an anti-fingerprint layer, etc. The base layer of the window WM may be composed of glass, sapphire, plastic, or the like. The base layer of the window WM may include an optically transparent insulating material. For example, the base layer of the window WM may include a glass or plastic film, or include a glass substrate and a plastic film bonded to each other by an adhesive.

The non-transmission region NTA may overlap the non-display region DD-NDA illustrated in FIG. 1, and have a shape corresponding to the non-display region DD-NDA. The non-transmission region NTA may be a region having relatively lower light transmittance than that of the transmission region TA. The non-transmission region NTA may be defined in a partial region of the base layer of the window WM, such as by a bezel pattern, and a region where the bezel pattern is not disposed or excluded may be defined as the transmission region TA. However, an embodiment of the invention is not limited thereto, and the non-transmission region NTA may also be omitted.

Although not illustrated in the drawings, the anti-reflection layer may be disposed between the window WM and the display module DM. The anti-reflection layer may reduce the reflectance for external light incident from the outside of the display device DD. The anti-reflection layer may include color filters. The color filters may have a predetermined arrangement. For example, the color filters may be arranged in consideration of light-emitting colors of pixels PX included on a display panel DP to be described later. In addition, the anti-reflection layer may further include a black matrix adjacent to the color filters.

According to an embodiment of the invention, the display module DM may include a display panel DP, and an input sensor ISU as an input sensing layer or panel.

The display panel DP may be any one among a liquid crystal display panel, an electrophoretic display panel, a microelectromechanical system (MEMS) display panel, an electrowetting display panel, an organic light-emitting display panel, an inorganic light-emitting display panel, and a quantum dot light-emitting display panel. However, an embodiment of the invention is not particularly limited thereto. Hereinafter, the display panel DP is described as the organic light-emitting display panel.

The input sensor ISU may include any one among a capacitance type sensor, an optical sensor, an ultrasonic sensor, and an electromagnetic induction sensor. The input sensor ISU may be formed (or provided) on the display panel DP through a continuous process, or manufactured (or provided) separately, then bonded to an upper side of the display panel DP through an adhesive member, and the input sensor ISU is not limited to any one embodiment of the invention.

The display device DD may further include a driving chip DC disposed on the display panel DP. The display device DD may further include a circuit board PB disposed on the display panel DP. In this embodiment, the circuit board PB may be a flexible circuit board, but an embodiment of the invention is not limited thereto. For example, the circuit board PB may be rigid. The circuit board PB may electrically connect the display panel DP and a main circuit board to each other.

The driving chip DC may include driving elements, for example, a data driving circuit, for driving pixels PX of the display panel DP. FIG. 2A illustrates a structure in which the driving chip DC is mounted on the display panel DP, but an embodiment of the invention is not limited thereto. For example, the driving chip DC may also be mounted on the circuit board PB. In this embodiment, the driving chip DC and the circuit board PB, directly mounted on the display panel DP, may be collectively referred to as an electronic component (or external component) of the display device DD. Hereinafter, description of the bonding structure of the display panel DP and the circuit board PB may be equally applied to another electronic component, such as the driving chip DC, other than the circuit board PB.

The display panel DP may include a bending region BA, and a non-bending region which is adjacent to the bending region BA. The non-bending region may be provided in plural including a first non-bending region NBA1 and a second non-bending region NBA2 arranged spaced apart from each other with the bending region BA therebetween, in (or along) a direction such as a first direction DR1.

The bending region BA may be defined as a region where the display panel DP is bendable about a virtual bending axis BX extending in a second direction DR2. The first non-bending region NBA1 may be a region overlapping the transmission region TA, and the second non-bending region NBA2 may be defined as a region where the circuit board PB is connected to the display module DM (or the display panel DP). When the bending region BA is bent about the bending axis BX, the circuit board PB and the driving chip DC may be disposed at a rear surface of the display panel DP such as to be disposed under the rear surface of the display panel DP. Although not illustrated in the drawing, additional components may be disposed in order to compensate a step difference, caused by the bending region BA, between the circuit board PB and the rear surface of the display panel DP.

According to an embodiment, the width of the first non-bending region NBA1 may be larger than the widths of the bending region BA and the second non-bending region NBA2, in the second direction DR2. However, an embodiment of the invention is not limited thereto, the width of the bending region BA in the second direction DR2 may be provided to decrease in a direction from the first non-bending region NBA1 to the second non-bending region NBA2, and is not limited to any one embodiment of the invention.

As illustrated in FIG. 2B, since a portion of the display panel DP is bent, the display device DD (or the display module DM) which is bent may include the circuit board PB, which is electrically bonded to the display panel DP, disposed on or facing the rear surface of the display panel DP.

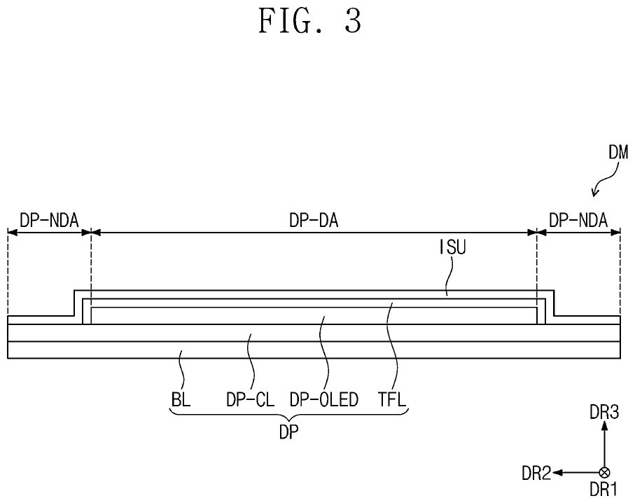

The accommodation member BC may accommodate the display module DM, and may be coupled to the window WM. The circuit board PB may be disposed on one end of the display panel DP, and electrically connected to the display panel DP at a circuit element layer DP-CL of the display panel DP to be described with reference to FIG. 3. Although not illustrated in the drawing, the display device DD may further include a main board, electronic modules mounted on the main board, a camera module, a power module, etc.

Although the mobile phone has been described as the display device DD, it is sufficient for the display device DD, in this specification, to include at least two electronic components bonded to each other. The display panel DP and the driving chip DC which is mounted on the display panel DP correspond to different electronic components, and these alone may constitute the display device DD. The display panel DP and the circuit board PB which is connected to the display panel DP also correspond to different electronic components, and these alone may constitute the display device DD. In addition, the main board and the electronic module mounted on the main board may constitute the display device DD. Hereinafter, the display device DD according to an embodiment of the invention is described focusing on a bonding structure of the display panel DP and the driving chip DC which is mounted on the display panel DP.

FIG. 3 is a cross-sectional view of a display module DM according to an embodiment of the invention.

Referring to FIG. 3, a display panel DP may include a base layer BL, a circuit element layer DP-CL disposed on the base layer BL, a display element layer DP-OLED, and an upper insulation layer TFL. An input sensor ISU may be disposed on the upper insulation layer TFL.

The display panel DP may include a display region DP-DA as a display area, and a non-display region DP-NDA as a non-display area. The display region DP-DA of the display panel DP may correspond to the display region DD-DA illustrated in FIG. 1 and/or the transmission region TA illustrated in FIG. 2A, and the non-display region DP-NDA may correspond to the non-display region DD-NDA illustrated in FIG. 1 and/or the non-transmission region NTA illustrated in FIG. 2A.

The base layer BL may include at least one plastic film. The base layer BL, which is a flexible substrate, may include a plastic substrate, a glass substrate, a metal substrate, an organic/inorganic composite material substrate, or the like.

The circuit element layer DP-CL may include at least one intermediate insulation layer and a circuit element. The intermediate insulation layer may include at least one inorganic intermediate layer and at least one organic intermediate layer. The circuit element may include signal lines, a driving circuit of a pixel, etc. An insulation layer, a semiconductor layer, and a conductive layer are formed through coating, deposition, etc. After this, the insulation layer, the semiconductor layer, and the conductive layer may be selectively patterned through photolithography and an etching process. Through such processes, a semiconductor pattern, a conductive pattern, a signal line, etc. are formed. Patterns disposed on the same layer may be formed through the same process. Hereinafter, patterns formed through the same process mean the patterns including the same material and the same stacked structure. As being in a same layer, elements may be formed (or provided) in a same process and/or include a same material as each other, elements may be respective portions of a same material layer, elements may be on a same layer by forming an interface with a same underlying or overlying layer, etc., without being limited thereto.

The display element layer DP-OLED may include a plurality of light-emitting elements OLED. The display element layer DP-OLED may further include an organic layer such as a pixel-defining film PDL.

The upper insulation layer TFL may seal the display element layer DP-OLED relative to other layers in the display module DM. The upper insulation layer TFL may be disposed on the display element layer DP-OLED. The upper insulation layer TFL may overlap the display region DP-DA and the non-display region DP-NDA. The upper insulation layer TFL may overlap at least a portion of the non-display region DP-NDA. For example, the upper insulation layer TFL may include a thin-film encapsulation layer as an encapsulation layer.

The thin-film encapsulation layer may include a stacked structure of an inorganic layer, an organic layer, and an inorganic layer. The upper insulation layer TFL may protect the display element layer DP-OLED from moisture, oxygen, and foreign substances such as dust particles. However, an embodiment of the invention is not limited thereto, and the upper insulation layer TFL may further include an additional insulation layer in addition to the thin-film encapsulation layer. For example, an optical insulation layer may further be included in order to control the refractive index.

According to an embodiment of the invention, an encapsulation substrate may be provided instead of the upper insulation layer TFL. In this case, the encapsulation substrate may be opposed to the base layer BL, and the circuit element layer DP-CL and the display element layer DP-OLED may be disposed between the encapsulation substrate and the base layer BL which face each other.

The input sensor ISU may be directly disposed on the display panel DP. In this specification, “component A being directly disposed on component B” means that there is no intervening layer disposed between component A and component B. In this embodiment, the input sensor ISU may be manufactured through a continuous process with the display panel DP. However, the technical scope of the invention is not limited thereto, and the input sensor ISU may be provided as an individual panel, and bonded to the display panel DP through an adhesive layer. For example, the input sensor ISU may be omitted.

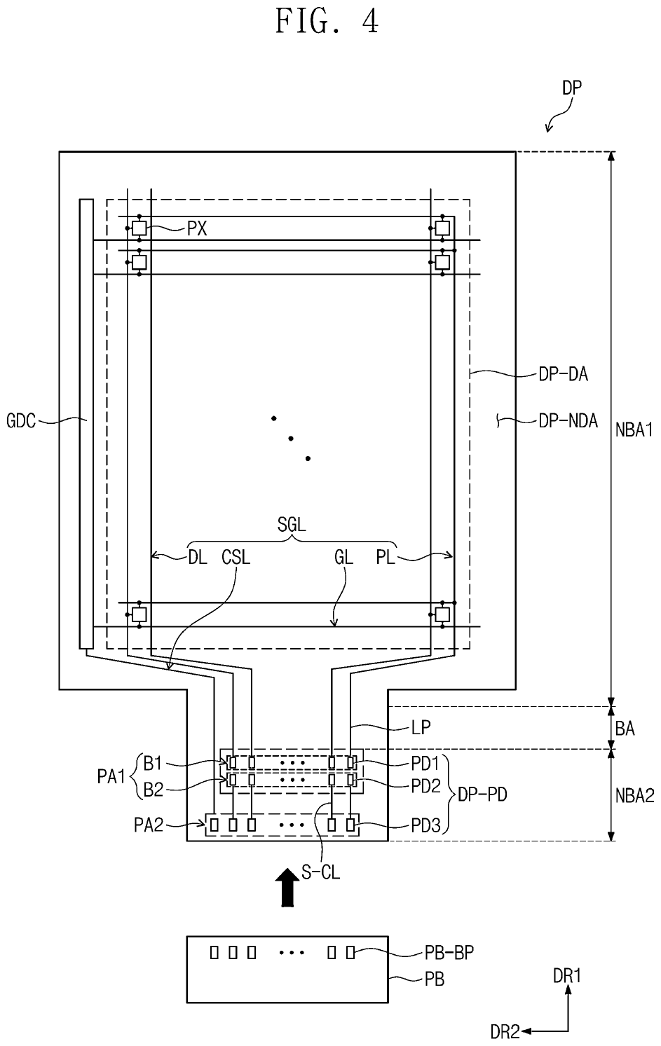

FIG. 4 is a plan view of a display panel DP according to an embodiment of the invention.

Referring to FIG. 4, the display panel DP may include a pixel PX provided in plural including a plurality of pixels PX, a gate driving circuit GDC, a plurality of signal lines SGL, and a signal pad DP-PD provided in plural including a plurality of signal pads DP-PD.

The pixels PX may be disposed in the display region DP-DA. Each of the pixels PX includes a light-emitting element OLED and a pixel driving circuit which is connected (e.g., electrically connected) thereto. In an embodiment, the light-emitting element OLED may be an organic light-emitting element. The gate driving circuit GDC sequentially outputs gate signals as electrical signals to a plurality of gate lines GL to be described later. One or more layer or pattern of a transistor of the gate driving circuit GDC may be formed through the same process as the process through which a layer or pattern of a transistor of the pixel PX is formed, for example, a low temperature polycrystalline silicon (LTPS) process or a low temperature polycrystalline oxide (LTPO) process. The display panel DP may also further include another driving circuit which provides an emission control signal for light emission, to the pixels PX.

The signal lines SGL may include gate lines GL, data lines DL, a power line PL, and a control signal line CSL. The gate lines GL may each be connected to a corresponding pixel PX among the pixels PX, and the data lines DL may each be connected to a corresponding pixel PX among the pixels PX. The power line PL may be connected to the pixels PX. The control signal line CSL may provide control signals as electrical signals to a scan driving circuit.

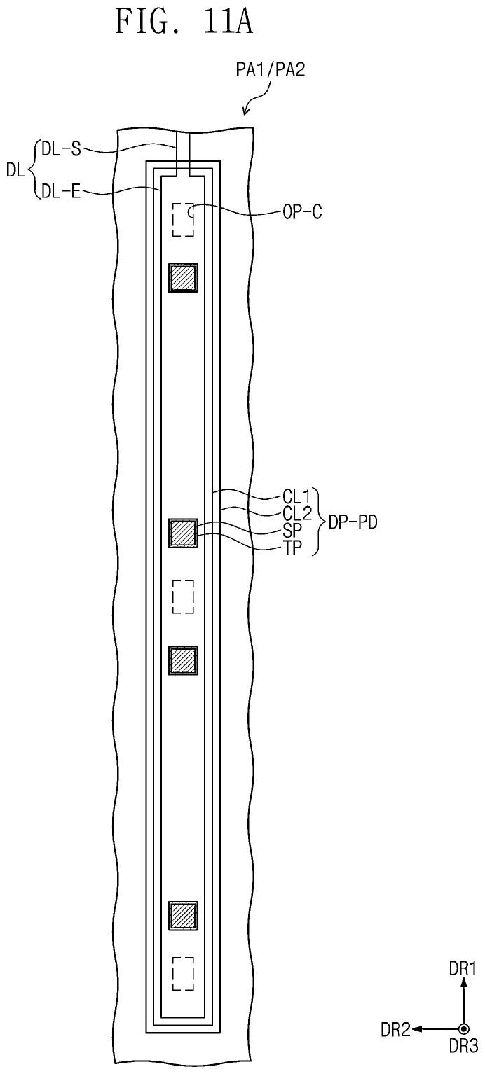

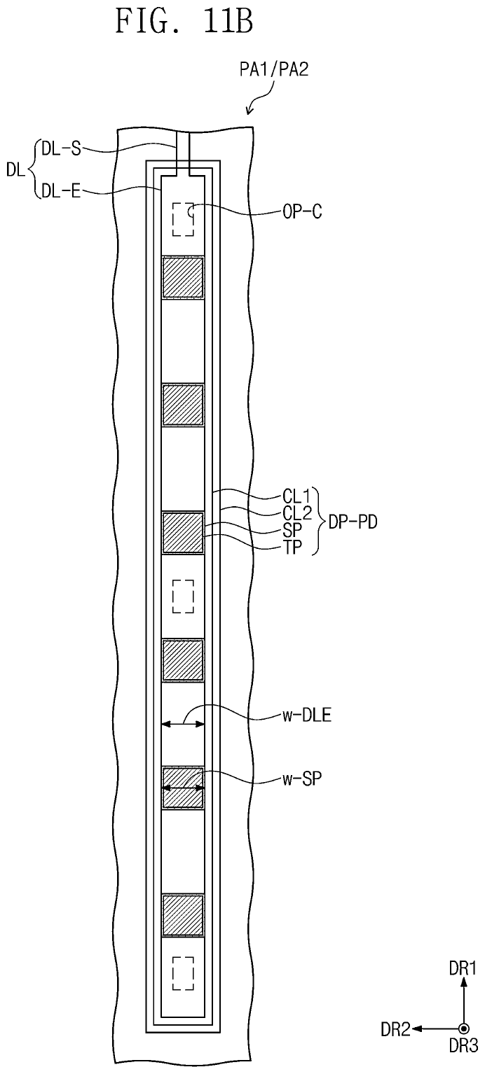

The signal lines SGL may overlap the display region DP-DA and the non-display region DP-NDA. The signal lines SGL may each include a line portion LP. Although not illustrated in the drawing, the signal lines SGL may each further include a pad portion. The line portion LP may overlap the display region DP-DA and the non-display region DP-NDA. The pad portion may be connected to an end of the line portion LP, such as an end which is furthest from the display area along a respective signal line. The connection of the pad portion and the line portion LP will be described in detail with reference to FIG. 11.

The plurality of signal pads DP-PD may include first pads PD1, second pads PD2, and third pads PD3. A region where the first and second pads PD1 and PD2 are disposed may be defined as a first pad region PA1, and a region where the third pads PD3 are disposed may be defined as a second pad region PA2.

The first pad region PA1 may be a region overlapping the driving chip DC shown in FIG. 2A, and the second pad region PA2 may be a region overlapping the circuit board PB shown in FIG. 2A. The first pad region PA1 may include a first region B1 or first area where the first pads PD1 are disposed, and a second region B2 or second area where the second pads PD2 are disposed. The first pad region PA1 and the second pad region PA2 may be disposed in the non-display region DP-NDA. The first pad region PA1 and the second pad region PA2 may be spaced apart from each other in a first direction DR1.

The first pad PD1 may be provided in plural to define a first pad row within the first region B1, the second pad PD2 may be provided in plural to define a second pad row within the second region B2, and the third pad PD3 may be provided in plural to define a third pad row within the second pad region PA2. It is exemplarily illustrated that one pad row is disposed in each of the first region B1 and the second region B2 of the first pad region PA1, but an embodiment of the invention is not limited thereto, and a plurality of pad rows may also be disposed in one of the respective regions or areas of the first pad region PA1.

The first pads PD1 may each be connected to a corresponding data line DL among the data lines DL. Although not illustrated in the drawing, the first pads PD1 and the second pads PD2 may be electrically connected to each other. Each of the second pads PD2 may be connected to each of the third pads PD3 through connection signal line S-CL.

The circuit board PB may include a plurality of substrate bump electrodes PB-BP. The substrate bump electrodes PB-BP may be arranged in a second direction DR2. The substrate bump electrodes PB-BP of the circuit board PB may be in contact with the third pads PD3 in the second pad region PA2 to be connected thereto. As being in contact, elements may form an interface therebetween. The bump electrodes of the circuit board PB may correspond to the third pads PD3 of the display panel DP, such as in location, size, etc.

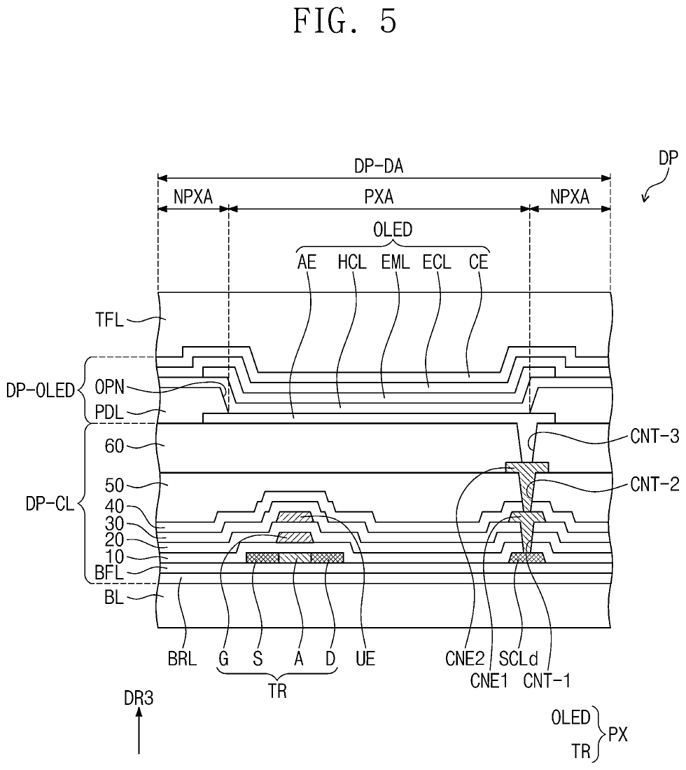

FIG. 5 is a cross-sectional view of a pixel PX according to an embodiment of the invention.

Referring to FIGS. 4 and 5, the display region DP-DA may include a light-emitting region PXA and a non-light-emitting region NPXA adjacent to each other. The pixels PX may each include a light-emitting element OLED and a pixel driving circuit connected thereto. In particular, the pixel PX may include a transistor TR as a circuit element and the light-emitting element OLED which is connected to the pixel driving circuit such as being connected thereto at the circuit element.

FIG. 5 exemplarily illustrates one transistor TR, but an embodiment of the invention is not limited thereto. The pixel PX according to an embodiment may include seven transistors and at least one capacitor, and the seven transistors and the capacitor may be variously electrically connected to each other. However, the number of each of the transistor and the capacitor constituting the pixel PX is not limited to any one embodiment of the invention.

The display panel DP may include a plurality of insulation layers, a semiconductor pattern, a conductive pattern, a conductive signal line, etc. The insulation layer, a semiconductor layer, and a conductive layer are formed (or provided) through coating, deposition, etc. After this, the insulation layer, the semiconductor layer, and the conductive layer may be selectively patterned through photolithography. In such ways, the semiconductor pattern, the conductive pattern, the conductive signal line, etc., included in a circuit element layer DP-CL and a display element layer DP-OLED, are formed.

A base layer BL may include a synthetic resin film. The base layer BL may have a multi-layer structure. For example, the base layer BL may have a three-layer structure of a synthetic resin layer, an inorganic layer, and a synthetic resin layer. In particular, the synthetic resin layer may be a polyimide-based resin layer, and the material is not particularly limited thereto. In addition, the base layer BL may include a glass substrate, a metal substrate, an organic/inorganic composite material substrate, or the like.

In an embodiment, the circuit element layer DP-CL may include a barrier layer BRL, a buffer layer BFL, first to sixth insulation layers 10 to 60, a transistor TR, a connection signal line SCLd, an upper electrode UE, a first connection electrode CNE1, and a second connection electrode CNE2.

At least one inorganic layer is disposed on an upper surface of the base layer BL. The inorganic layer may be formed in or include multiple layers. The barrier layer BRL may be disposed on the base layer BL. The buffer layer BFL may be disposed on the barrier layer BRL. The barrier layer BRL and the buffer layer BFL may be inorganic layers.

The semiconductor pattern is disposed on the buffer layer BFL. The semiconductor pattern may include polysilicon. However, an embodiment of the invention is not limited thereto, and the semiconductor pattern may include amorphous silicon or metal oxide.

FIG. 5 only illustrates a part of the semiconductor pattern, and the semiconductor pattern may be further disposed in another region of the pixel PX on a plane, such as to include semiconductor patterns in a semiconductor layer of the circuit element layer DP-CL. The semiconductor pattern may be arranged in a certain rule across the pixels PX. The semiconductor pattern may vary in electrical property according to whether a region or area is doped or not. The semiconductor pattern may include a first region and a second region. The first region may be doped with an N-type dopant or a P-type dopant. A P-type transistor includes a doped region doped with a P-type dopant.

The first region has higher conductivity (e.g., electrical conductivity) than that of the second region, and substantially serves as a transistor electrode or a transistor signal line. The second region may be a region doped with low concentration, or an undoped region, and substantially corresponds to an active region (or channel) of the transistor. In other words, a portion of the semiconductor pattern may be the active region of the transistor, another portion may be a source region or a drain region of the transistor, and another portion may be a connection electrode or a connection signal line.

As illustrated in FIG. 5, the source S as a source region, the active A as an active region, and the drain D as a drain region of the transistor TR may be formed from a semiconductor layer.

FIG. 5 illustrates a portion of the connection signal line SCLd formed from the semiconductor layer, such as to be in a same layer as the semiconductor pattern of the transistor TR. In an embodiment, the connection signal line SCLd may be electrically connected to any drain D among the transistors in the pixel PX.

A first insulation layer 10 is disposed on the buffer layer BFL. The first insulation layer 10 may cover the semiconductor pattern. The first insulation layer 10 may overlap the plurality of pixels PX in common. A gate G is disposed on the first insulation layer 10. The gate G may be a portion of a metal pattern in a first metal material layer. The gate G may overlap the active A. In an method of providing the display panel DP, the gate G may function as a mask in a doping process of the underlying semiconductor material layer.

A second insulation layer 20 which covers the gate G may be disposed on the first insulation layer 10. The second insulation layer 20 may overlap the pixels PX in common. The upper electrode UE may be disposed on the second insulation layer 20. The upper electrode UE may overlap the gate G of the transistor TR. The upper electrode UE may be a portion of a metal pattern in a second metal material layer. A portion of the gate G and the upper electrode UE overlapping therewith may define the capacitor.

A third insulation layer 30 which covers the upper electrode UE may be disposed on the second insulation layer 20. The first connection electrode CNE1, disposed on the third insulation layer 30, may be connected to the connection signal line SCLd through (or at) a first contact hole CNT-1 passing through the first to third insulation layers 10 to 30.

A fourth insulation layer 40 which covers the first connection electrode CNE1 may be disposed on the third insulation layer 30. The first to fourth insulation layers 10 to 40 may each be an inorganic layer and/or an organic layer, and have a single-layer or multi-layer structure.

In an embodiment, the first connection electrode CNE1 may also be disposed on the fourth insulation layer 40, and covered by a fifth insulation layer 50. Alternatively, according to an embodiment of the invention, both of the first connection electrode CNE1, disposed on the third insulation layer 30 and covered by the fourth insulation layer 40, and the first connection electrode CNE1, disposed on the fourth insulation layer 40 and covered by the fifth insulation layer 50, may be included.

The fifth insulation layer 50 may be disposed on the fourth insulation layer 40. The fifth insulation layer 50 may be an organic layer. The second connection electrode CNE2 may be disposed on the fifth insulation layer 50. The second connection electrode CNE2 may be connected to the first connection electrode CNE1 through a second contact hole CNT-2 passing through the fourth insulation layer 40 and the fifth insulation layer 50.

A sixth insulation layer 60 which covers the second connection electrode CNE2 may be disposed on the fifth insulation layer 50. The sixth insulation layer 60 may be an organic layer. A first electrode AE may be disposed on the sixth insulation layer 60. The first electrode AE may be connected to the second connection electrode CNE2 through a third contact hole CNT-3 passing through the sixth insulation layer 60. The first through third contact holes CNT-1 through CNT-3 may be in communication with each other to collectively define a contact hole.

The circuit element layer DP-CL may include a plurality of connection electrodes connected to the transistors, and some of the plurality of connection electrodes may be disposed on different layers from each other. Although not illustrated in the drawing, the first connection electrode CNE1 may extend along the DR1-DR2 plane to be connected to the transistor TR. The positions of the plurality of connection electrodes are not limited to any one embodiment of the invention.

The display element layer DP-OLED may include a pixel-defining film PDL and a light-emitting element OLED. The pixel-defining film PDL as a pixel defining layer may have (or define) a pixel opening OPN defined therein. The pixel opening OPN of the pixel-defining film PDL may expose at least a portion of the first electrode AE to outside the pixel-defining film PDL. In this embodiment, the light-emitting region PXA may be defined to correspond to an area or region of the portion of the first electrode AE which is exposed to outside the pixel-defining layer by the pixel opening OPN.

A hole control layer HCL may be disposed in the light-emitting region PXA and the non-light-emitting region NPXA in common. The hole control layer HCL may include a hole transport layer, and further include a hole injection layer. A light-emitting layer EML may be disposed on the hole control layer HCL. The light-emitting layer EML may be disposed in a region corresponding to the pixel opening OPN. That is, the light-emitting layer EML may be formed separately for each pixel PX, such as to be a discrete pattern. However, an embodiment of the invention is not limited thereto, and the light-emitting layer EML may also be formed across the plurality of pixels PX in common, such as by using an open mask in a method of providing the display panel DP.

An electron control layer ECL may be disposed on the light-emitting layer EML. The electron control layer ECL may include an electron transport layer and further include an electron injection layer. The hole control layer HCL and the electron control layer ECL may be formed across the pixels PX in common such as by using an open mask in a method of providing the display panel DP.

A second electrode CE may be disposed on the electron control layer ECL. The second electrode CE may have an integrated form, and disposed across the pixels PX in common. An upper insulation layer TFL may be disposed on the second electrode CE. The upper insulation layer TFL may include a plurality of thin films stacked along the thickness direction.

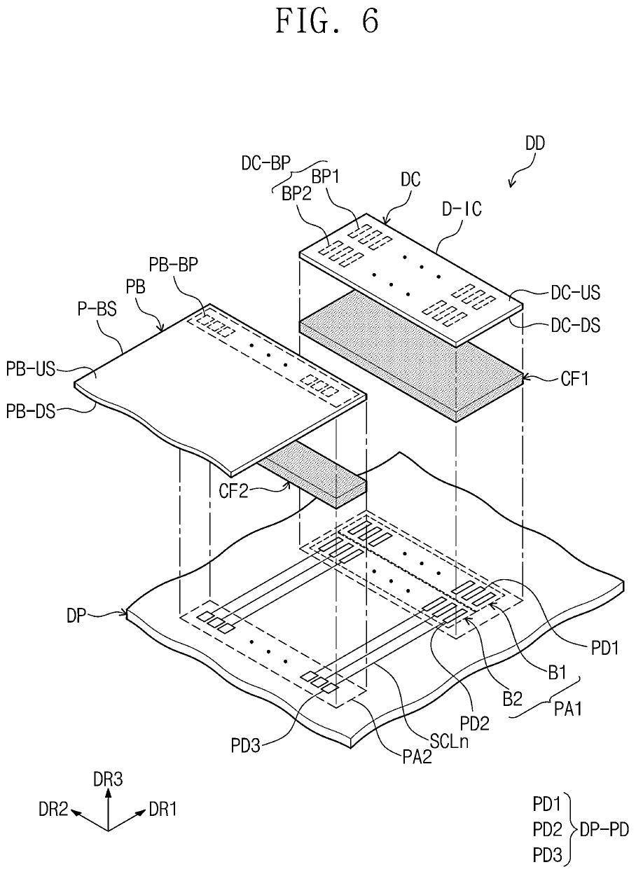

FIG. 6 is an enlarged exploded perspective view illustrating first and second pad regions PA1 and PA2 of a display device DD according to an embodiment of the invention. FIG. 6 exemplarily illustrates a driving chip DC and a circuit board PB exploded from a display panel DP. First pads PD1, second pads PD2, connection signal lines SCLn, and third pads PD3 in FIG. 6 are respectively the same as the first pads PD1, the second pads PD2, the connection signal lines SCLn, and the third pads PD3 in FIG. 4, and thus the descriptions thereof will be omitted or simplified.

Referring to FIGS. 4 and 6, the driving chip DC may be bonded to the display panel DP, at a first pad region PA1 thereof, through a first adhesive layer CF1. The circuit board PB may be bonded to the display panel DP, at a second pad region PA2 thereof, through a second adhesive layer CF2. The first and second adhesive layers CF1 and CF2 may include synthetic resins having adhesiveness. According to this embodiment, the first and second adhesive layers CF1 and CF2 may not include (e.g., exclude) a conductive element such as a conventional conductive ball, and include only the synthetic resins having conductivity, such as to provide a conductive adhesive pattern or layer.

The driving chip DC may include a driving integrated circuit D-IC and chip bump electrodes DC-BP which are mounted in the driving chip DC. The driving integrated circuit D-IC may include an upper surface DC-US as a chip upper surface and a lower surface DC-DS as a chip lower surface, and the lower surface DC-DS may be a surface facing the first and second pads PD1 and PD2 such as to be closer to the display panel DP than the chip upper surface. The chip bump electrodes DC-BP may be disposed on the lower surface DC-DS of the driving integrated circuit D-IC.

The chip bump electrodes DC-BP may include first bumps BP1 electrically connected to the display panel DP, at the first pads PD1, respectively, and second bumps BP2 electrically connected to the display panel DP, at the second pads PD2, respectively. The first bumps BP1 may be arranged along a second direction DR2, and the second bumps BP2 may be spaced apart from the first bumps BP1 in a first direction DR1 and arranged along the second direction DR2.

The driving chip DC may receive first signals as electrical signals from the outside (e.g., outside of the display device DD, through the second pads PD2 and the second bumps BP2. The driving chip DC may provide second signals as electrical signals, generated on the basis of the first signals, to the first pads PD1 through the first bumps BP1. For example, the driving chip DC may include a data driving circuit. The first signal may be an image signal which is a digital signal applied from the outside, and the second signal may be a data signal which is an analog signal. The driving chip DC may generate an analog voltage corresponding to a grayscale value of the image signal. The data signal may be provided to the pixel PX through the data line DL illustrated in FIG. 4.

Although not illustrated in the drawing, the first bumps BP1 and the second bumps BP2 may protrude from the lower surface DC-DS of the driving integrated circuit D-IC and/or be exposed to the outside of the driving chip DC. When the first adhesive layer CF1 hardens or is provided in a hardened form, the first pads PD1 and the first bumps BP1 may be fixed in contact with each other, and the second pads PD2 and the second bumps BP2 may be fixed in contact with each other, to electrically connect the display panel DP to the driving chip DC.

The circuit board PB may include a base board layer P-BS and substrate bump electrodes PB-BP which are mounted in the circuit board PB. The circuit board PB may include an upper surface PB-US as an upper board surface and a lower surface PB-DS as a lower board surface, and the lower surface PB-DS may be a surface facing the third pads PD3 such as to be closer to the display panel DP than the upper board surface. The substrate bump electrodes PB-BP may be disposed on the lower surface PB-DS of the base board layer P-BS. The substrate bump electrodes PB-BP may be electrically connected to the display panel DP, at the third pads PD3, respectively. The substrate bump electrodes PB-BP may be arranged along the second direction DR2. The circuit board PB may provide an image signal, a driving voltage, and other control signals to the driving chip DC.

Although not illustrated in the drawing, the substrate bump electrodes PB-BP may protrude from or be exposed at the lower surface PB-DS of the base board layer P-BS to be exposed to the outside of the circuit board PB. When the second adhesive layer CF2 hardens or is provided in a hardened form, the third pads PD3 and the substrate bump electrodes PB-BP may be fixed in contact with each other, to electrically connect the display panel DP to the circuit board PB.

An electronic component may include a component substrate and a component bump electrode which is disposed on a lower side of the component substrate. In a case where the electronic component corresponds to the driving chip DC, the component substrate may correspond to the driving integrated circuit D-IC of the driving chip DC, and the component bump electrode may correspond to the chip bump electrode DC-BP. Alternatively, in a case where the electronic component corresponds to the circuit board PB, the component substrate may correspond to the base board layer P-BS of the circuit board PB, and the component bump electrode may correspond to the substrate bump electrode PB-BP.

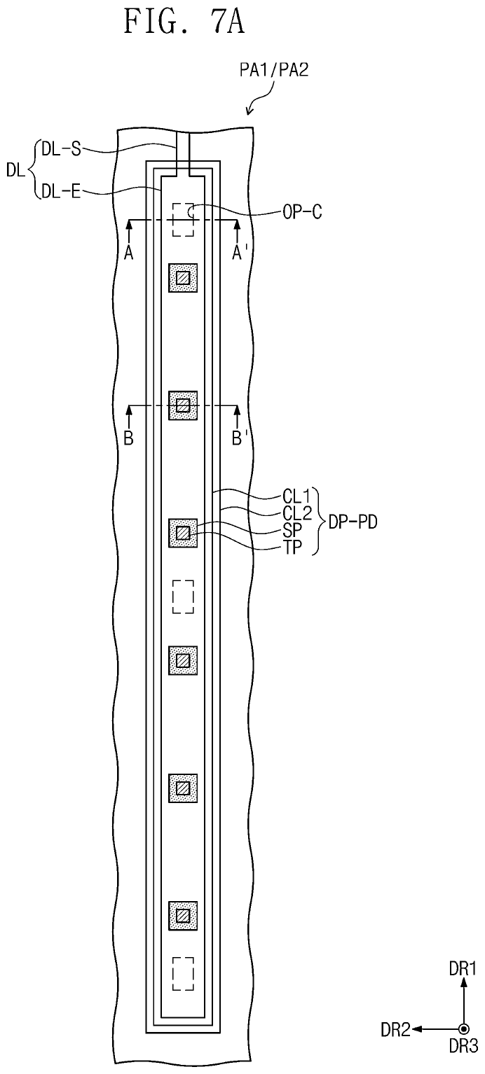

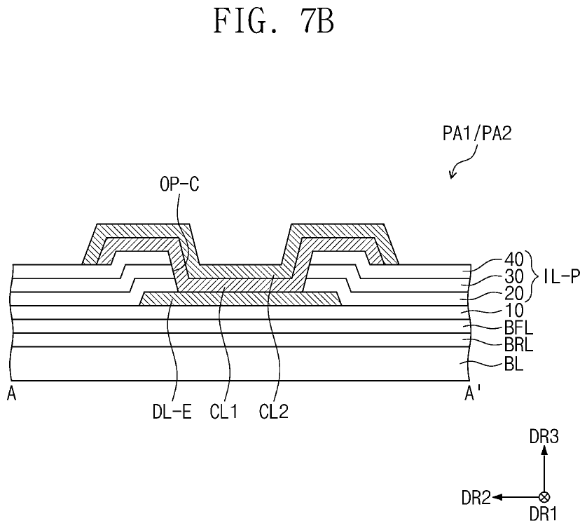

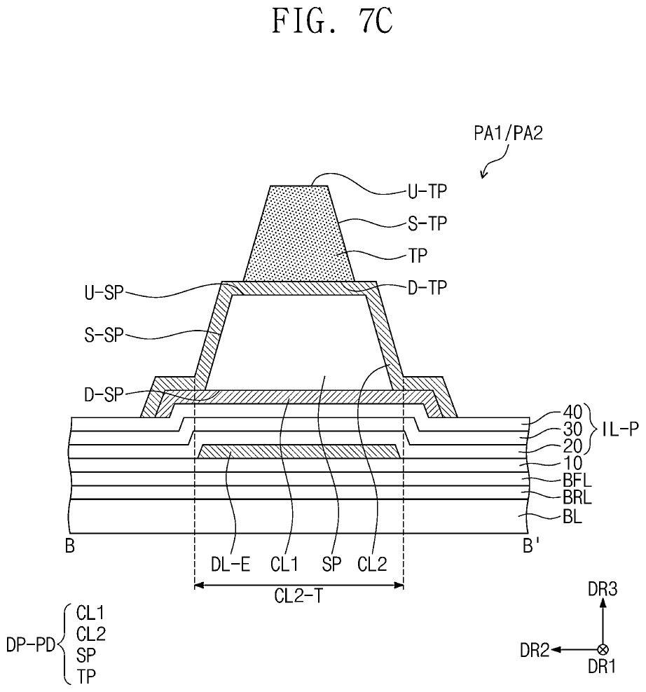

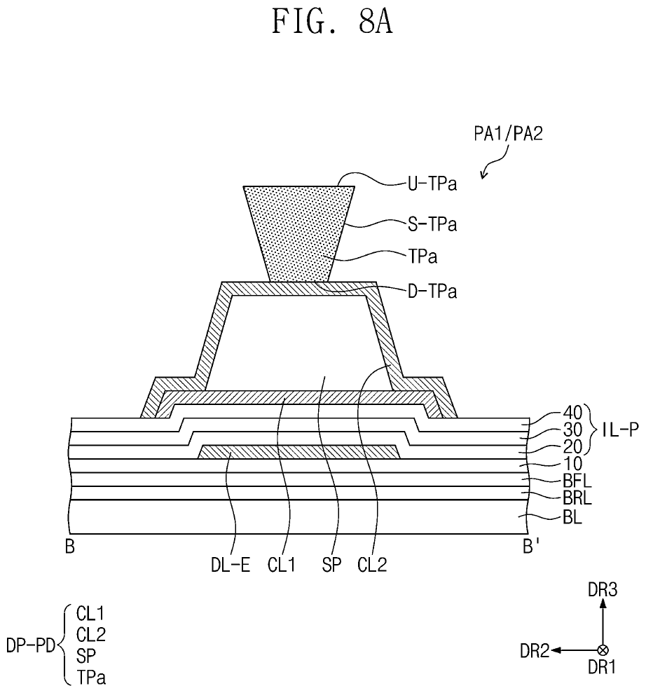

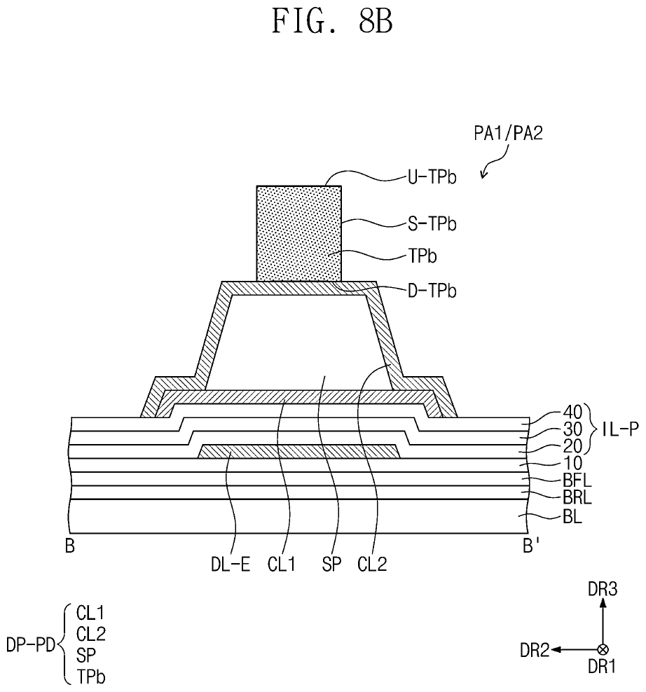

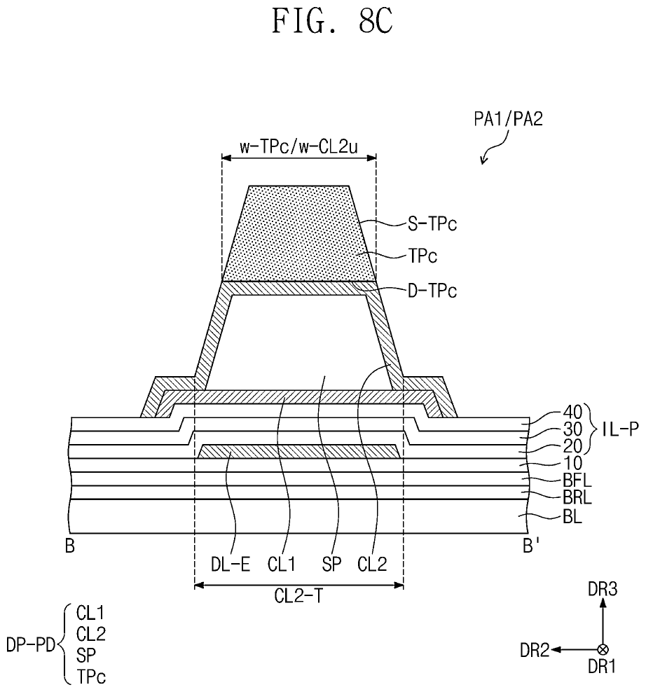

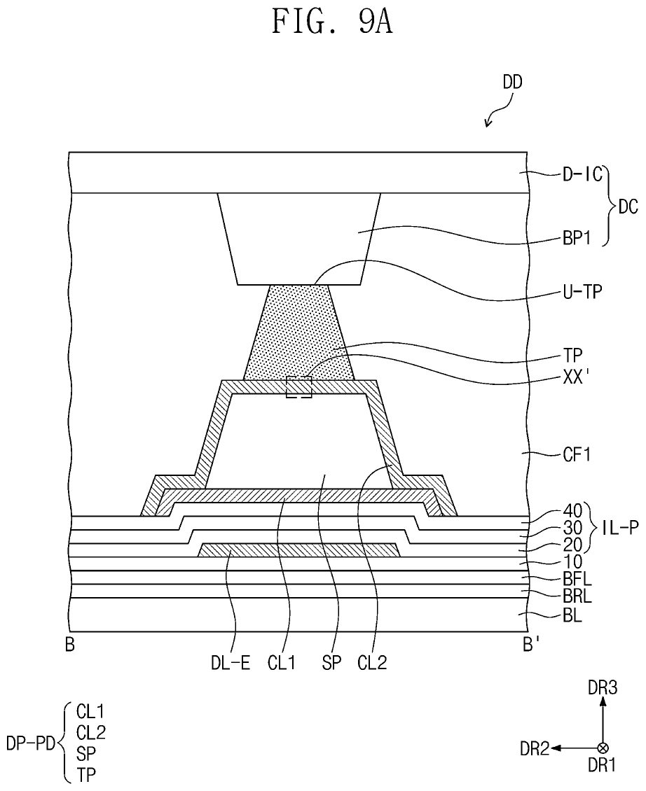

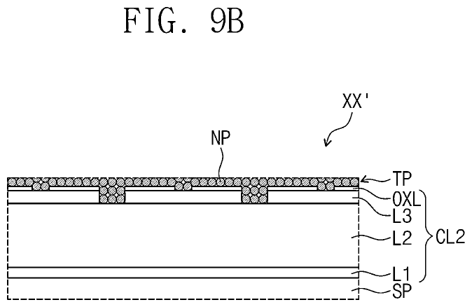

FIG. 7A is a plan view schematically illustrating the first and/or second pad regions PA1 and PA2 according to an embodiment of the invention. FIGS. 7B and 7C are cross-sectional views corresponding to FIG. 7A. FIGS. 8A to 8C are cross-sectional views corresponding to FIG. 7A. FIG. 9A is a cross-sectional view illustrating a bonding structure of a display device DD according to an embodiment of the invention. FIG. 9B is an enlarged cross-sectional view of region XX′ of FIG. 9A. FIG. 7B is a cross-sectional view of pad regions PA1 and PA2 taken along line A-A′ of FIG. 7A, and FIG. 7C and FIGS. 8A to 8C are cross-sectional views of the pad regions PA1 and PA2 taken along line B-B′ of FIG. 7A. While cross-sectional structures are shown in a DR2-DR3 plane, it will be understood that the cross-sections in FIGS. 7B through 8C may represent structures in a DR1-DR3 plane.

An individual signal pad DP-PD (or signal pad structure) illustrated in FIGS. 7A to 9 may represent any one among the plurality of signal pads DP-PD including the first to third pads PD1 to PD3 described with reference to FIGS. 4 and 6. A major planar dimension of a structure may define a length thereof, and a planar dimension intersecting the major dimension may define a width thereof. FIG. 7A illustrates a data line DL, including an end portion DL-E furthest from the display area along a length (e.g., first direction DR1) of the data line DL, and a line portion DL-S having different widths (e.g., second direction DR2) from each other, as an example of a conductive signal line, but an embodiment of the invention is not limited thereto. The conductive signal line may be a different signal line other than the data line DL, and the end portion DL-E and the line portion DL-S may also have a uniform width without distinction therebetween. The line portion DL-S may correspond to the line portion LP in FIG. 4. The end portion DL-E may correspond to the aforementioned pad portion among the signal pads DP-PD in FIG. 4.

Hereinafter, the first and second pad regions PA1 and PA2 will be described focusing on a first pad region PA1 where the date line DL is disposed. For a second pad region PA2, the description of the first pad region PA1 may be applied, except for the connection signal line S-CL (see FIG. 3) being disposed instead of the data line DL.

Referring to FIG. 7A, the signal pad DP-PD may include a first conductive pattern CL1, a second conductive pattern CL2, at least one insulation pattern SP, and at least one protruding pattern TP. Referring to FIG. 7B, the first conductive pattern CL1 may be connected to the end portion DL-E of the data line DL, through at least one contact hole OP-C as a pad contact hole. FIG. 7A exemplarily illustrates the signal pad DP-PD including three contact holes OP-C, six insulation patterns SP, and six protruding patterns TP.

On a plane, the end portion DL-E may have a shape extending in a first direction DR1, that is, having a length (major dimension) along the first direction DR1. That is, the end portion DL-E may have a dimension in the first direction DR1 larger than the dimension in a second direction DR2.

On a plane, the contact holes OP-C may overlap the end portion DL-E. The contact holes OP-C may be arranged along the first direction DR1. The contact holes OP-C may be disposed apart from each other (e.g., spaced apart form each other) in the first direction DR1. In an embodiment, the contact holes OP-C may be disposed on one side (first end or upper side) of the end portion DL-E in the first direction DR1, the other side (second end or lower side) of the end portion DL-E in the first direction DR1 which is opposite to the one side, and the center part of the end portion DL-E, respectively. On a plane, a portion of the first conductive pattern CL1 may overlap the contact holes OP-C.

On a plane, the insulation patterns SP may overlap the second conductive pattern CL2. On a plane, the insulation patterns SP may be disposed outside the contact holes OP-C, such as to be spaced apart therefrom. In this embodiment, the insulation patterns SP may be arranged along the first direction DR1. The insulation patterns SP may be disposed apart from each other in the first direction DR1.

In this embodiment, the insulation patterns SP may be disposed between adjacent contact holes OP-C. In an embodiment, some of the insulation patterns SP may be disposed between the contact hole OP-C disposed on the upper side and the contact hole OP-C disposed on the center part, and the others of the insulation patterns SP may be disposed between the contact hole OP-C disposed on the lower side and the contact hole OP-C disposed on the center part. FIG. 7A exemplarily illustrates that three insulation patterns SP are disposed between the contact holes OP-C disposed on the upper side and on the center part, and between the contact holes OP-C disposed on the lower side and on the center part.

FIG. 7A exemplarily illustrates the insulation patterns SP in a square shape on a plane (e.g., planar shape of a square), but an embodiment of the invention is not limited thereto. The shape of the insulation patterns SP may be changed to a planar shape, such as polygon, circle, oval, etc., other than the square. In addition, the insulation patterns SP are not limited to having the same shape as each other.

On a plane, at least portions of the protruding patterns TP may overlap the insulation patterns SP, respectively. In this embodiment, the insulation patterns SP may overlap the protruding patterns TP, respectively. That is, the protruding patterns TP may be disposed respectively corresponding to the insulation patterns SP. In this embodiment, the protruding patterns TP may each overlap the corresponding insulation pattern SP on a plane. The protruding patterns TP may each be disposed inside the corresponding insulation pattern SP on a plane. That is, in a plan view, the protruding patterns TP may have a size or area which is equal to or smaller than that of the corresponding insulation pattern SP, to be disposed inside the corresponding insulation pattern SP. A respective protruding pattern TP may be spaced apart from an outer edge of the corresponding insulation pattern SP, in the plan view, without being limited thereto. An entirety of the protruding conductive pattern (e.g., the protruding pattern TP) of the second conductive layer CL2 may be overlapped by the insulation pattern SP.

Referring to FIGS. 7B to 8C, the end portion DL-E may be disposed on a first insulation layer 10. The end portion DL-E may be disposed on the same layer (or in the same layer) as the layer on which the gate G, illustrated in FIG. 5, is disposed. The end portion DL-E may be formed through the same process as that of the gate G. The end portion DL-E may include the same material as that of the gate G.

However, the position of the end portion DL-E is not limited thereto. The end portion DL-E may be disposed on or in the same layer as the layer on which the upper electrode UE, illustrated in FIG. 5, is disposed, include the same material as that of the upper electrode UE, and have the same stacked structure as that of the upper electrode UE. Some of the plurality of signal lines may be formed through the same process as the process through which the gate G (see FIG. 5) is formed, and others may be formed through the same process as the process through which the upper electrode UE (see FIG. 5) is formed.

The data line DL may be disposed on one layer and have an integrated form, but an embodiment of the invention is not limited thereto. One data line DL may include a plurality of portions disposed on different layers from each other. For example, the line portion DL-S (see FIG. 7A) may include at least two portions.

The first conductive pattern CL1 may be disposed on a fourth insulation layer 40. The first conductive pattern CL1 may be connected to the end portion DL-E through a contact hole OP-C passing through second to fourth insulation layers 20, 30, and 40. That is, the first conductive pattern CL1 may be in contact with the end portion DL-E through the contact hole OP-C. The second to fourth insulation layers 20, 30, and 40 may be formed through the same process as the process through which the second to fourth insulation layers 20, 30, and 40 of the display region DP-DA, illustrated in FIG. 4, are formed.

In this specification, a collection of the insulation layers disposed between the end portion DL-E and the first conductive pattern CL1 may be defined as a pad insulation layer IL-P. In this embodiment, the second to fourth insulation layers 20, 30, and 40 may be defined as the pad insulation layer IL-P. The stacked structure of the pad insulation layer IL-P may vary according to the stacked structure of a circuit element layer DP-CL. In an embodiment, the contact hole OP-C may be defined in the insulation layers the number of which is larger or smaller than the number of the second to fourth insulation layers 20, 30, and 40.

The first conductive pattern CL1 and the end portion DL-E may be separated from each other by the pad insulation layer IL-P disposed therebetween, for example, the second to fourth insulation layers 20, 30, and 40.

The second conductive pattern CL2 may be disposed on the first conductive pattern CL1. A region of the second conductive pattern CL2 not overlapping the insulation pattern SP may be in contact with the first conductive pattern CL1. That is, a portion of the second conductive pattern CL2 which is adjacent to the insulation pattern SP in the plan view (e.g., non-overlapping), may contact the first conductive pattern CL1.

In an embodiment, the first conductive pattern CL1 may be formed through the same process as the process through which the first connection electrode CNE1, previously described with reference to FIG. 5, is formed, and the second conductive pattern CL2 may be formed through the same process as the process through which the second connection electrode CNE2, previously described with reference to FIG. 5, is formed. The first conductive pattern CL1 may include the same material as that of the first connection electrode CNE1 (see FIG. 5), and the second conductive pattern CL2 may include the same material as that of the second connection electrode CNE2 (see FIG. 5), such as to be in same layers, respectively.

FIGS. 7A and 7B exemplarily illustrate an embodiment in which the first conductive pattern CL1 is disposed on the fourth insulation layer 40. According to an embodiment of the invention, the first conductive pattern CL1 may be disposed on the third insulation layer 30, and in this case, the fourth insulation layer 40 may not be disposed in one or more of the first and second pad regions PA1 or PA2 (e.g., may be omitted from a respective pad region). However, an embodiment of the invention is not limited thereto, and the combination of the connection electrodes, formed through the same processes as the processes through which the first and second conductive patterns CL1 and CL2 are formed, may be variously selected according to the stacked structure of the circuit element layer DP-CL as long as providing the first and second conductive patterns CL1 and CL2 which are disposed on different layers.

It is exemplarily illustrated that the second conductive pattern CL2 has a larger planar area than that of the first conductive pattern CL1. The second conductive pattern CL2 is extended further than an edge of the first conductive pattern CL1, and the second conductive pattern CL2 covers the edge of the first conductive pattern CL1, but an embodiment of the invention is not limited thereto. The second conductive pattern CL2 may have substantially the same planar area as that of the first conductive pattern CL1, and the edge of the second conductive pattern CL2 may be substantially aligned with the edge of the first conductive pattern CL1, along the thickness direction. Here, outer side surfaces of the first conductive pattern CL1, and the second conductive pattern CL2 may be aligned with each other, such as being coplanar with each other.

A portion of the second conductive pattern CL2 may include an overlapping portion overlapping the insulation pattern SP on a plane. The insulation pattern SP may be disposed between the first conductive pattern CL1 and the second conductive pattern CL2 on a cross-section, e.g., along the thickness direction. The insulation pattern SP may be disposed on the first conductive pattern CL1 and covered by the second conductive pattern CL2. The second conductive pattern CL2 may cover an upper surface U-SP and a side surface S-SP of the insulation pattern SP. In this specification, a lower surface D-SP of the insulation pattern SP is defined as a surface in contact with the first conductive pattern CL1, and the upper surface U-SP of the insulation pattern SP is defined as a surface opposed to the lower surface D-SP and in contact with the second conductive pattern CL2.

The insulation pattern SP may have a trapezoid shape on a cross-section. The insulation pattern SP may have the side surface S-SP with a slope, and the slope which the side surface S-SP makes with respect to the lower surface D-SP may form an acute angle. However, an embodiment of the invention is not limited thereto, and the insulation pattern SP may have a rectangular shape on a cross-section, or also have a reversed trapezoid shape.

The insulation pattern SP may include polymer. The insulation pattern SP may include thermosetting polymer. However, an embodiment of the invention is not limited thereto, and the insulation pattern SP may include thermoplastic polymer.

In an embodiment, the insulation pattern SP may be formed through the same process as the process through which the fifth insulation layer 50 (see FIG. 5) is formed, such that the insulation pattern SP and the fifth insulation layer 50 are in a same layer (e.g., a same material layer) as each other. Accordingly, an additional process may not be required for the forming of the insulation pattern SP. However, an embodiment of the invention is not limited thereto, the combination of the connection electrodes, formed through the same processes as the processes through which the first and second conductive patterns CL1 and CL2 are formed, may be variously selected according to the stacked structure of the circuit element layer DP-CL, and accordingly, the insulation layer, formed through the same process as the process through which the insulation pattern SP is formed, may also be variously selected.

A portion of the second conductive pattern CL2 covering the insulation pattern SP may protrude from or be disposed relative to the first conductive pattern CL1 in the third direction DR3 more than another (or remaining) portion of the second conductive pattern CL2. The portion of the second conductive pattern CL2 which protrudes may be referred to as a protruding portion CL2-T. The second conductive pattern CL2 may be in contact with an upper surface of the first conductive pattern CL1 at an area not overlapping the insulation pattern SP, the side surface S-SP of the insulation pattern SP, and the upper surface U-SP of the insulation pattern SP. That is, the protruding portion CL2-T may correspond to or be defined a portion of the second conductive pattern CL2 which is in contact with the side surface S-SP of the insulation pattern SP and the upper surface U-SP of the insulation pattern SP.

The protruding pattern TP may be disposed on the second conductive pattern CL2. More particularly, the protruding pattern TP may be disposed on the protruding portion CL2-T of the second conductive pattern CL2. The protruding pattern TP may be disposed on a portion of the protruding portion CL2-T covering the upper surface U-SP of the insulation pattern SP. Here, within the signal pad DP-PD, the second conductive pattern CL2 includes a protruding portion CL2-T which is extended along the insulation pattern SP and protrudes from the first conductive pattern CL1, and the protruding conductive pattern TP protrudes from the protruding portion CL2-T of the second conductive pattern CL2. Referring to FIG. 7C, for example, the first conductive pattern CL1 extends further than a side surface of the insulation pattern SP to define an upper surface of the first conductive pattern CL1 which is exposed outside of the insulation pattern SP. The second conductive pattern CL2 may further include the protruding portion CL2-T in contact with the side surface and an upper surface of the insulation pattern SP, and an extended portion which extends from the protruding portion CL2-T and further from the insulation pattern SP than the first conductive pattern CL1, the extended portion contacting the upper surface of the first conductive pattern CL1.

The protruding pattern TP may include a metal material. The protruding pattern TP may be formed through reverse offset printing to be described later. The protruding pattern TP may be formed by a print pattern, including metal ink, being sintered. The metal ink may include metal nanoparticles. Accordingly, the protruding pattern TP may include the metal nanoparticles. This will be described in detail later.

The protruding pattern TP may include an upper surface U-TP, a lower surface D-TP opposed to the upper surface U-TP, and a side surface S-TP which connects the upper surface U-TP to the lower surface D-TP. In this specification, the lower surface D-TP of the protruding pattern TP is defined as a surface in contact with the second conductive pattern CL2, and the upper surface U-TP of the protruding pattern TP is defined as a surface opposed to the lower surface D-TP and facing an electronic component.

As illustrated in FIG. 7C, according to an embodiment of the invention, the protruding pattern TP may have a trapezoid shape on a cross-section. The upper surface U-TP of the protruding pattern TP may have a smaller width than that of the lower surface D-TP of the protruding pattern TP, and a slope of the side surface S-TP of the protruding pattern TP with respect to the lower surface D-TP may form an acute angle. However, the shape of the protruding pattern TP is not limited thereto.

As illustrated in FIG. 8A, according to an embodiment of the invention, a protruding pattern TPa may also have a reversed trapezoid shape on a cross-section. An upper surface U-TPa of the protruding pattern TPa may have a larger width than that of a lower surface D-TPa of the protruding pattern TPa, and a slope of a side surface S-TPa of the protruding pattern TPa with respect to the lower surface D-TPa may form an obtuse angle.

Alternatively, as illustrated in FIG. 8B, according to an embodiment of the invention, a protruding pattern TPb may also have a rectilinear shape such as a rectangular shape or a square shape on a cross-section. An upper surface U-TPb of the protruding pattern TPb may have substantially the same width as that of a lower surface D-TPb of the protruding pattern TPb, and a slope of a side surface S-TPb of the protruding pattern TPb with respect to the lower surface D-TPb may form a right angle.

Referring to FIGS. 7C, 8A and 8B, a portion of the uppermost surface of the second conductive pattern CL2 extends outward from the respective conductive protrusion (e.g., the protruding pattern TP), to be exposed outside of the conductive protrusion. That is, side surfaces of the conductive protrusion and the second conductive pattern CL2 may be unaligned.

Alternatively, as illustrated in FIG. 8C, according to an embodiment of the invention, a first width w-TPc defined at a lower surface D-TPc of a protruding pattern TPc may be substantially the same as a second width w-CL2u of a portion of a protruding portion CL2-T, of a second conductive pattern CL2, covering an upper surface U-SP of an insulation pattern SP to form the uppermost surface. A side surface S-TPc of the protruding pattern TPc may be substantially aligned with an outer side surface of a portion of the second conductive pattern CL2 which covers a side surface S-SP of the insulation pattern SP. Here, the side surface S-TPc and the outer side surface may be coplanar with each other, without being limited thereto.

The shape of the protruding pattern TPc is not limited to any one embodiment of the invention, and may vary according to conditions of a printing process of the protruding pattern and an ink used in the printing process (for example, material, content for the material, etc.). While the protruding pattern TPc in FIG. 8C has a trapezoid shape in cross-section, the cross-sectional shape may be variously changed such as to be an inverted trapezoid (see FIG. 8A), a rectilinear shape (FIG. 8B), and the like.

FIG. 9A exemplarily illustrates a driving chip DC as an electronic component of the display device DD. FIG. 9A illustrates that a first bump BP1, among the chip bump electrodes DC-BP (see FIG. 6) of the driving chip DC, is in contact with a protruding pattern TP of a pad electrode (e.g., such as the signal pad PD1). In an embodiment, for example, a display device DD includes a display module DM (or display panel DP) including a pixel PX, a signal line (like the data line DL) electrically connected to the pixel PX and defining an end portion DL-E furthest from the pixel PX, and a signal pad DP-PD electrically connected to the signal line and to which an electrical signal is provided from an electronic component external to the display module DM. The signal pad DP-PD includes a first conductive pattern CL1 at which the signal pad DP-PD is electrically connected to the end portion DL-E of the signal line, a second conductive pattern CL2 facing the first conductive pattern CL1 and electrically connected to the first conductive pattern CL1, an insulation pattern SP between the first conductive pattern CL1 and the second conductive pattern CL2 which face each other, and a protruding conductive pattern (e.g., protruding pattern TP) at which the signal pad DP-PD is electrically connected to the electronic component, the protruding conductive pattern protruding from the second conductive pattern CL2 and overlapping the insulation pattern SP.

Due to bonding pressure during a method of electrically connecting the electronic component to the display panel DP, the first bump BP1 of the driving chip DC may pass through a thickness portion of a first adhesive layer CF1 to come into contact with the protruding pattern TP. The first adhesive layer CF1 which is finally formed may surround outer side surfaces of the protruding pattern TP and the first bump BP1, to promote a stable physical connection therebetween. The first adhesive layer CF1 before hardening may have lower viscosity than that of an anisotropic conductive film. On the other hand, a conventional anisotropic conductive film has relatively high viscosity in order to maintain the alignment of conductive elements (e.g., balls or other shapes) therein.

Since the protruding pattern TP protrudes toward the first bump BP1, the protruding pattern TP and the first bump BP1 may come into contact with each other more closely, and contact resistance (e.g., electrical resistance) therebetween may be reduced. As the conventional conductive balls are omitted, short circuit defects caused by the conductive balls may be reduced even though signal pads DP-PD are dense. As accessibility between the signal pad DP-PD and the first bump BP1 becomes improved to increase the electrical contact therebetween, bonding pressure for contacting the signal pad DP-PD and the first bump BP1 to each other may be reduced. As the bonding pressure is reduced, physical damages to a display panel DP or an electronic component, which occur during the bonding process, may be reduced.

According to an embodiment of the invention, the signal pad DP-PD may include an insulation pattern SP and a protruding pattern TP, and the protruding pattern TP may be disposed on the insulation pattern SP as a conductive contact and have a shape protruding from the insulation pattern SP. The insulation pattern SP may provide high restoring force from or impact absorbance of bonding pressure when the protruding pattern TP and the first bump BP1 may come into contact with each other, and through this, the protruding pattern TP and a bump electrode (for example, first bump BP1) may come into close contact with each other.

In addition, since the protruding pattern TP, physically in contact with the bump electrode, is disposed on the insulation pattern SP, a component directly in contact with the bump electrode may have little or no deformation even though the shape of the insulation pattern SP is deformed due to bonding pressure during a bonding process. That is, the protruding pattern TP may have a stable electrical connection with the bump electrode despite the deformation of the insulation pattern SP due to the bonding pressure, and bonding resistance between the protruding pattern TP and the bump electrode may be reduced. Accordingly, it may be possible to provide a display device DD having improved bonding reliability.

Referring to FIG. 9B, a second conductive pattern CL2 according to an embodiment may include a first layer L1, a second layer L2, and a third layer L3 stacked in sequence. The first layer L1 may cap a lower side of the second layer L2, and the third layer L3 may cap an upper side of the second layer L2. The second layer L2 may be thicker than the first and third layers L1 and L3. The second layer L2 may include a material having higher conductivity than that of each of the first and third layers L1 and L3. The first and third layers L1 and L3 may include the same material, and the second layer L2 may include a different material from the material of the first and third layers L1 and L3. For example, the first and third layers L1 and L3 may include titanium (Ti), and the second layer L2 may include aluminum (Al). In an embodiment, an oxide film OXL may further be formed on an interface of the third layer L3 to cover the third layer L3. The oxide film OXL, formed on the interface of the third layer L3, may include titanium oxide (TiOₓ). The thickness portion at the third layer L3 and the thickness portion at the oxide film OXL may together be considered a third layer L3 within the second conductive pattern CL2.

In this embodiment, in a bonding process of a method of electrically connecting the electronic component to the display panel DP, as bonding pressure is applied to a protruding pattern TP and the second conductive pattern CL2, some of metal nanoparticles NP in the protruding pattern TP may remove a portion of the oxide film OXL. In addition, others of the metal nanoparticles NP in the protruding pattern TP may also remove a portion of the third layer L3. That is, material of the protruding pattern TP may penetrate the oxide film OXL and/or the third layer L3. Accordingly, a portion of the second layer L2 of the second conductive pattern CL2 may be exposed to outside the third layer L3 and the oxide film OXL at respective recessed defined therein. That is, the protruding pattern TP may include a portion directly in contact with the second layer L2 of the second conductive pattern CL2, as well as the third layer L3 thereof.

Electrical contact resistance in a case where the protruding patterns TP are in contact with the oxide film OXL and/or the third layer L3, may be higher than electrical contact resistance in a case where the protruding patterns TP are in contact with the second layer L2. That is, since the protruding patterns TP have relatively low contact resistance when in contact with the second layer L2, the protruding patterns TP and the second conductive pattern CL2 may have a more stable connection with each other. According to this embodiment, since the protruding patterns TP are formed to include a portion directly in contact with the second layer L2, contact resistance between the protruding patterns TP and the second conductive pattern CL2 may be reduced, thereby forming a signal pad DP-PD in which components are physically and electrically stably connected to each other.

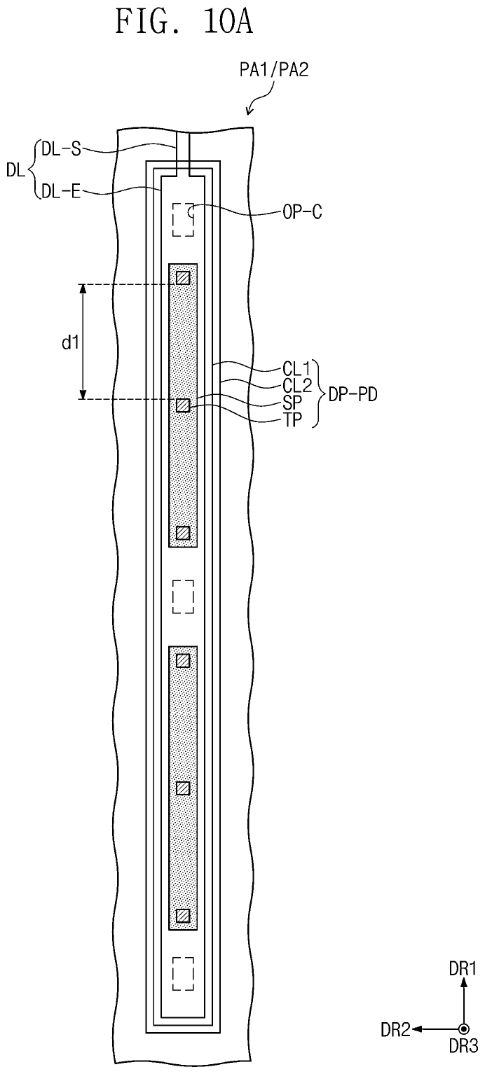

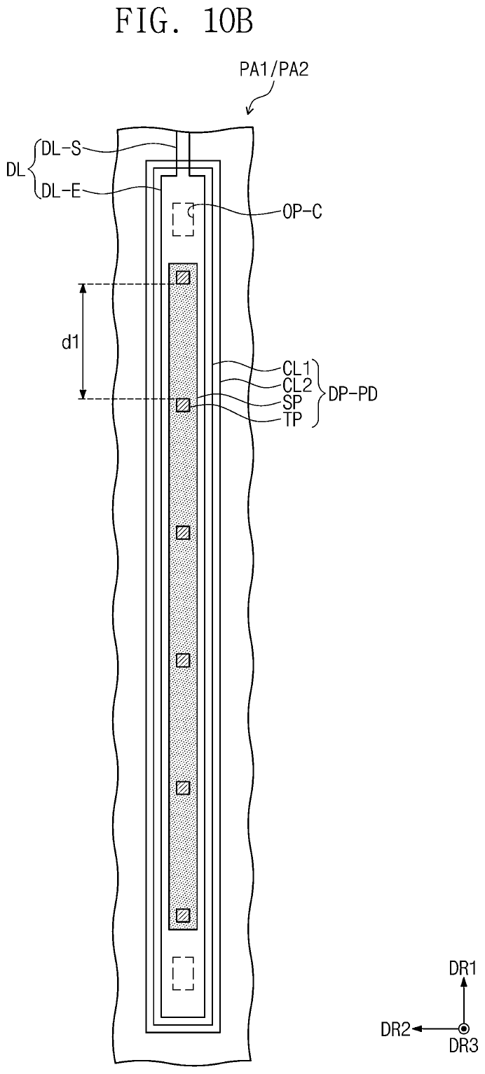

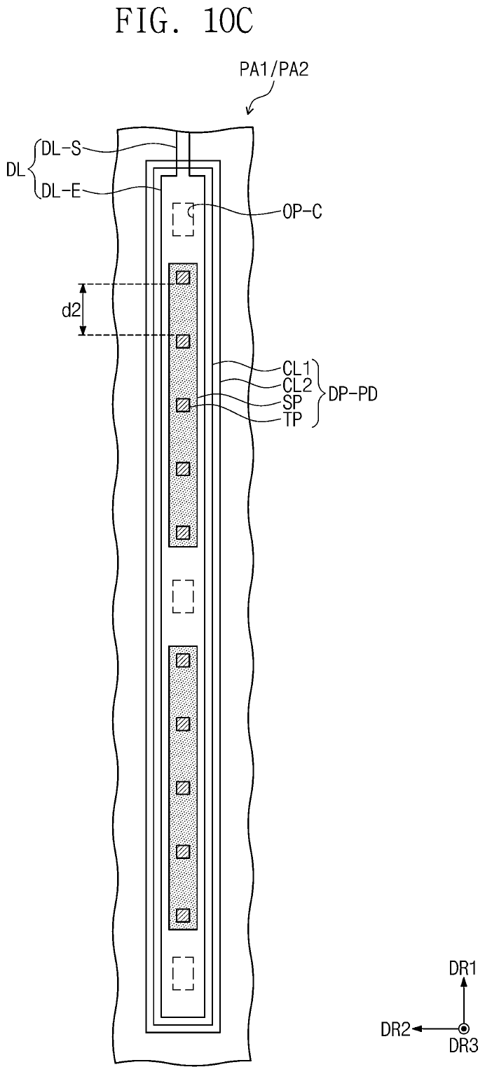

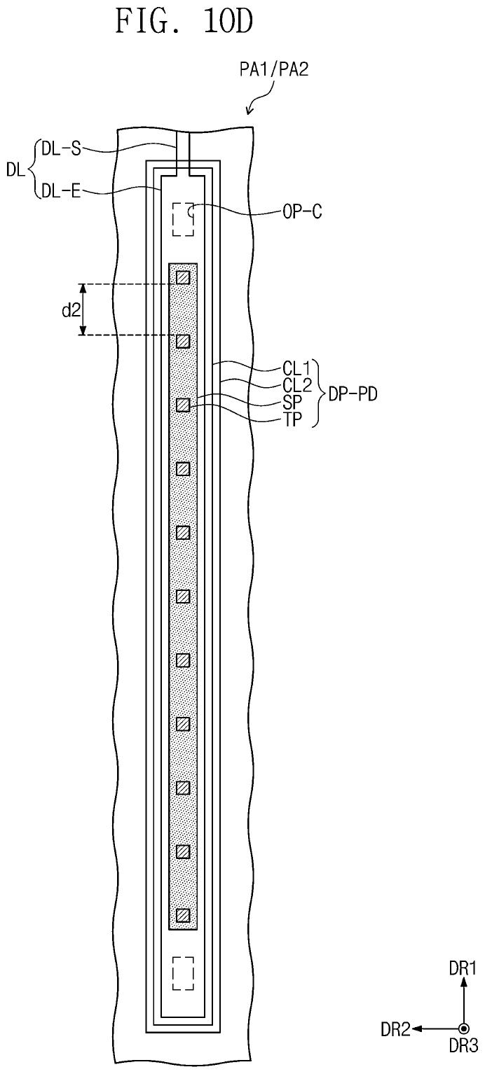

FIGS. 10A to 10D are plan views schematically illustrating pad regions PA1 and PA2 according to an embodiment of the invention. Same/similar components as/with the components described with reference to FIGS. 1 to 9 are denoted as the same/similar reference numerals or symbols, and duplicate descriptions will be omitted and differences will be mainly described.

Referring to FIGS. 10A to 10D, in this embodiment, the number of protruding patterns TP disposed on a same one insulation pattern SP may be set in various ways. The number of the insulation patterns SP disposed between adjacent contact holes OP-C within a signal pad, may also be set in various ways. The number of the contact holes OP-C disposed overlapping an end portion DL-E may also be set in various ways.

As illustrated in FIGS. 10A to 10D, one insulation pattern SP may be disposed between adjacent contact holes OP-C. The insulation pattern SP may have a shape lengthwise extending in a first direction DR1. That is, the insulation pattern SP may have a length dimension in the first direction DR1 larger than the width dimension in a second direction DR2. The insulation pattern SP may have a rectangular shape on a plane. A plurality of protruding patterns TP may be disposed on the one insulation pattern SP. The protruding patterns TP may be arranged on the one insulation pattern SP, spaced apart from each other along the first direction DR1.

FIGS. 10A and 10C exemplarily illustrate that three contact holes OP-C and two insulation patterns SP are disposed on one single end portion DL-E.

FIGS. 10B and 10D exemplarily illustrate that two contact holes OP-C and one single insulation pattern SP therebetween are disposed on the end portion DL-E. The two contact holes OP-C may be respectively disposed on one side (or upper side) of the end portion DL-E in the first direction DR1, and on the other side (or lower side) of the end portion DL-E in the first direction DR1, respectively.

In addition, in this embodiment, the distance between the protruding patterns TP may be set in various ways.

FIGS. 10A and 10B illustrate that adjacent protruding patterns TP are disposed apart from each other by a first distance d1. FIG. 10A exemplarily illustrates that three protruding patterns TP are disposed on one insulation pattern SP, so that total six protruding patterns TP are disposed on two insulation patterns SP, for a same signal pad. FIG. 10B exemplarily illustrates that six protruding patterns TP are disposed on one insulation pattern SP, for a same one signal pad.

FIGS. 10C and 10D illustrate that adjacent protruding patterns TP are disposed apart from each other by a second distance d2. The second distance d2 may be smaller than the first distance d1. That is, FIGS. 10C and 10D illustrate that the protruding patterns TP are arranged at narrower intervals than the protruding patterns TP illustrated in FIGS. 10A and 10B. FIG. 10C exemplarily illustrates that five protruding patterns TP are disposed on one insulation pattern SP, so that total ten protruding patterns TP are disposed on two insulation patterns SP, within a same signal pad. FIG. 10D exemplarily illustrates that eleven protruding patterns TP are disposed on one insulation pattern SP, within a same signal pad.

The numbers of the contact holes OP-C, the insulation patterns SP, and the protruding patterns TP are not limited to what are illustrated in FIGS. 10A to 10D, and may be set in various ways, within a single one of the signal pad.

FIGS. 11A and 11B are plan views schematically illustrating pad regions PA1 and PA2 according to an embodiment of the invention. Same/similar components as/with the components described with reference to FIGS. 1 to 9 are denoted as the same/similar reference numerals or symbols, and duplicate descriptions will be omitted and differences will be mainly described.

Referring to FIG. 11A, in this embodiment, protruding patterns TP may respectively overlap insulation patterns SP, and the number of the insulation patterns SP disposed between adjacent contact holes OP-C may be set in various ways.

FIG. 11A exemplarily illustrates that two insulation patterns SP and two protruding patterns TP, respectively overlapping the two insulation patterns SP, are disposed between adjacent contact holes OP-C, but an embodiment of the invention is not limited thereto. One insulation pattern SP and one protruding pattern TP may be disposed, and four or more insulation patterns SP and four or more protruding patterns TP may also be disposed between the adjacent contact holes OP-C. Here, a width w-SP of the insulation pattern SP in the second direction DR2 may be smaller than a width w-DLE of an end portion DL-E in the second direction DR2.

Referring to FIG. 11B, in this embodiment, the protruding patterns TP may be disposed respectively overlapping the insulation patterns SP, and the planar size of the insulation patterns SP may be set in various ways. That is, the dimension of the insulation pattern SP in a first direction DR1 and the dimension of the insulation pattern SP in a second direction DR2 may be set in various ways. As illustrated in FIG. 11B, in an embodiment, the width w-SP of the insulation pattern SP in the second direction DR2 may be substantially the same as a width w-DLE of an end portion DL-E in the second direction DR2.

Hereinafter, a method of manufacturing (or providing) a display device DD according to an embodiment will be described with reference to the drawings. For the description of the manufacturing method of the display device DD according to an embodiment, contents overlapping with the contents for the aforementioned display device DD, according to an embodiment, will be omitted.

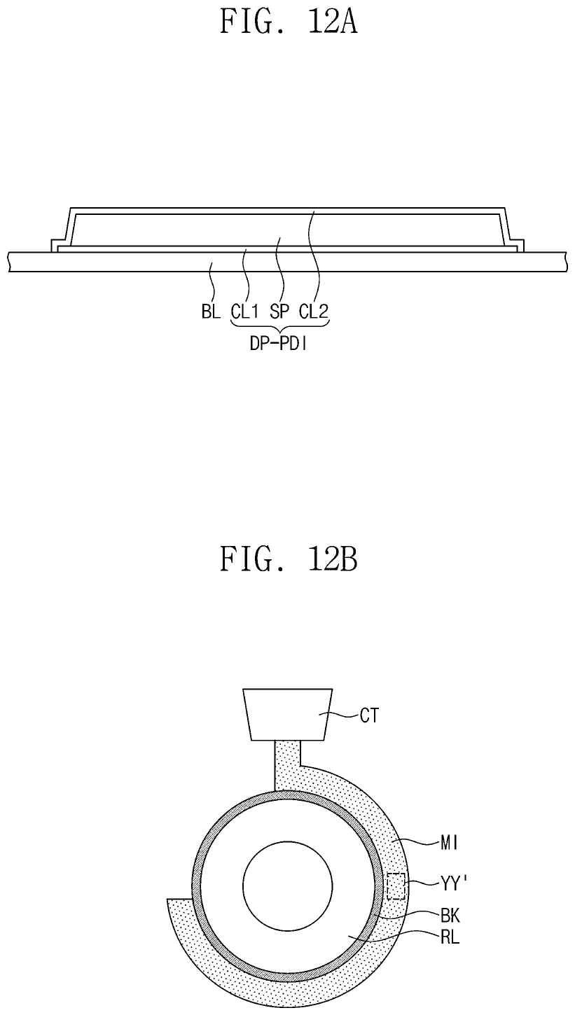

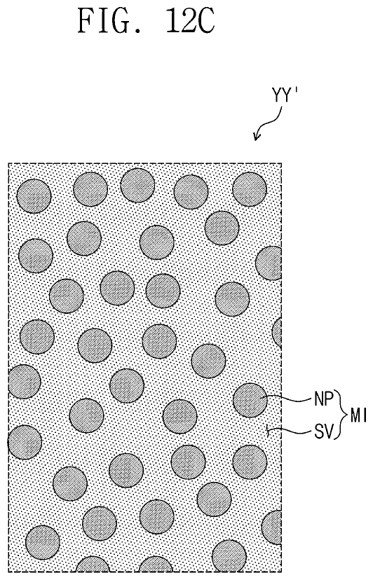

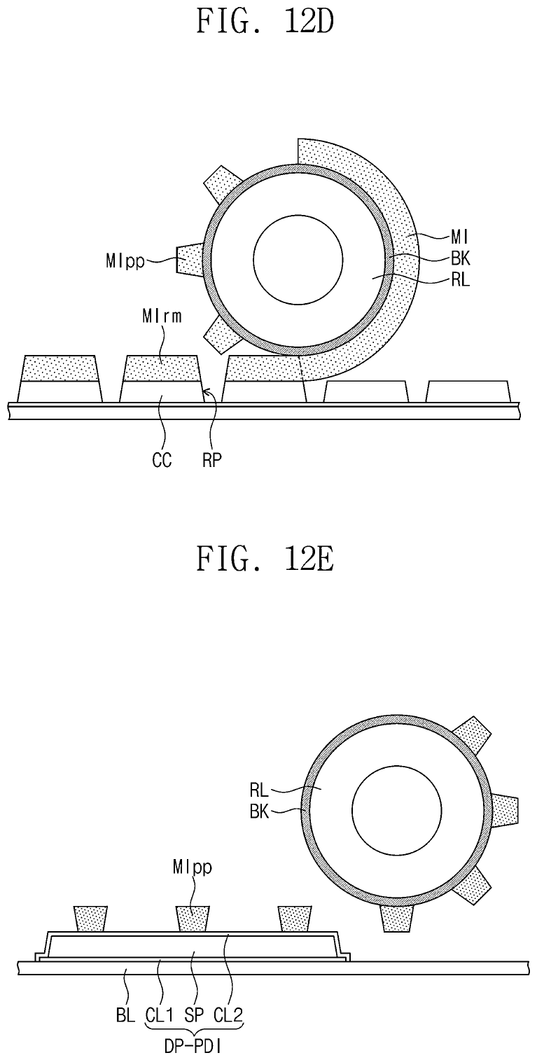

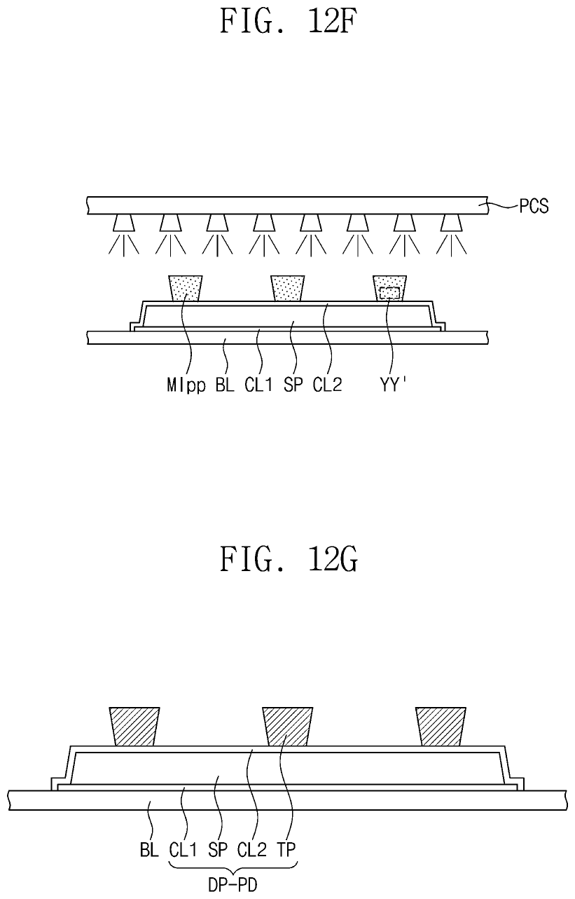

FIGS. 12A to 12G are cross-sectional views illustrating processes or operations of a manufacturing method of a display device DD according to an embodiment of the invention.

The manufacturing method of the display device DD, according to an embodiment of the invention, may include providing a preliminary signal pad DP-PDI containing a first conductive pattern CL1 connected to a signal line (such as the data line DL, etc.), a second conductive pattern CL2 disposed on the first conductive pattern CL1, and an insulation pattern SP disposed between the first conductive pattern CL1 and the second conductive pattern CL2, and forming a protruding pattern TP on the preliminary signal pad DP-PDI to form a signal pad DP-PD. In an embodiment, the forming of the protruding pattern TP may be performed through a reverse offset printing process. That is, a method of providing a signal pad DP-PD of a display device DD includes providing a preliminary signal pad DP-PDI and providing a protruding conductive pattern on the preliminary signal pad DP-PDI, to form the signal pad DP-PD of the display module DM at which the display module DM of the display device DD is connected to an electronic component of the display device DD.

Referring to FIGS. 12A to 12G, the method of manufacturing or providing the display device DD according to an embodiment of the invention may include the providing of the preliminary signal pad DP-PDI, and the forming (or providing) of the protruding pattern TP, to form the signal pad DP-PD at which the display panel DP is connected to an electronic component of the display device DD.

Referring to FIG. 12A, the preliminary signal pad DP-PDI may include the first conductive pattern CL1, the second conductive pattern CL2 disposed on the first conductive pattern CL1, and the insulation pattern SP disposed between the first conductive pattern CL1 and the second conductive pattern CL2. FIG. 12A schematically illustrates that the preliminary signal pad DP-PDI is provided onto a base layer BL, but the barrier layer BRL, the buffer layer BFL, the first insulation layer 10, the signal line (for example, data line DL), and the pad insulation layer IL-P, illustrated in FIGS. 5, 7B, and 7C, may further be disposed between the base layer BL and the preliminary signal pad DP-PDI. The first conductive pattern CL1 may be connected to the signal line (for example, the data line DL).

Referring to FIGS. 12B to 12G, the providing of the protruding pattern TP relative to the preliminary signal pad DP-PDI may be performed through a reverse offset printing process.

Referring to FIG. 12B, the forming of the protruding pattern TP (see FIG. 12G) according to an embodiment of the invention may include applying metal ink MI onto a blanket BK.

The blanket BK may be wound around a roll RL having a cylindrical shape. A coater device CT may be used as a coater for application of the metal ink MI onto a target object, such as the blanket BK. The roll RL may be rotated, and at the same time, the metal ink MI may be applied onto the entire surface of the blanket BK through the coater device CT. In an embodiment, the applying of the metal ink MI may be performed through slit coating.

FIG. 12C is an enlarged cross-sectional view illustrating region YY′ of FIG. 12B. Referring to FIG. 12C, the conductive material of the metal ink MI may include a solvent SV and metal nanoparticles NP which are dispersed in the solvent SV. Here, the providing of the protruding conductive pattern may include providing a layer of metal ink MI including a solvent SV and metal nanoparticles NP, onto a blanket BK movable relative to the preliminary signal pad DP-PDI.

In an embodiment, the metal nanoparticles NP may contain copper (Cu) or silver (Ag). However, an embodiment of the invention is not limited thereto, and the metal ink MI may include various types of conductive or metal nanoparticles NP as long as being evenly dispersed in the solvent SV in the form of nanoparticle, and having conductivity in a sintered state.

In an embodiment, for the solvent SV, a water, methanol, ethanol, alcohol, glycol, acetate, ether, ketone, hydrocarbon-based, aromatic, and halogen-substituted solvent, a dimethyl sulfoxide solvent, a combination thereof, or the like may be used, but an embodiment of the invention is not limited thereto.

The metal ink MI may further include a binder. The binder may not reduce densification between the metal nanoparticles NP. Alternatively, the metal ink MI may further include a dispersant. The dispersant may improve dispersion stability of the metal ink MI. Alternatively, the metal ink MI may further include a surfactant or a viscosity controlling agent.

Referring to FIG. 12D, the providing of the protruding pattern TP (see FIG. 12G) according to an embodiment of the invention may include transferring portions of the metal ink MI, which is applied onto the blanket BK, to a cliché CC as a receiving pattern.

The metal ink MI applied onto the blanket BK may be transferred to the cliché CC by contacting the cliché CC. Concave patterns RP may be formed or defined between solid portions of the cliché CC, and the concave patterns RP may correspond to a shape of the protruding patterns TP (see FIG. 12E) of the display panel DP to be formed later.

The metal ink MI which comes into contact with the cliché CC, among the metal ink MI applied onto the blanket BK, may remain on the cliché CC (e.g., a remaining metal material), and may be removed from the blanket BK. The metal ink MI remaining on the cliché CC may be referred to as a removed pattern MIrm. The metal ink MI not in contact with the cliché CC due to separation of the metal ink MI by the concave patterns RP, among the metal ink MI applied onto the blanket BK, may remain on the blanket BK as protrusions of the metal ink MI. Accordingly, print patterns MIpp as the protrusions of the metal ink MI having a shape corresponding to the protruding patterns TP (see FIG. 12E), to be formed later, may be provided on the blanket BK to be rotatable therewith along the roller (e.g., roll ROL).

Referring to FIG. 12E, the forming of the protruding pattern TP (see FIG. 12G) according to an embodiment of the invention may include transferring the print patterns MIpp as protrusions of the metal ink MI from the blanker BK which is on the roller, to a stacked structure of the preliminary display panel, (e.g., at the preliminary signal pad DP-PDI).

In this embodiment, the print patterns MIpp may be transferred onto a preliminary signal pad DP-PDI. The preliminary signal pad DP-PDI corresponds to the preliminary signal pad DP-PDI which is provided in the providing of the preliminary signal pad DP=PDI, previously described with reference to FIG. 12A. More particularly, the print patterns MIpp may be transferred onto a portion of the second conductive pattern CL2 which protrudes by being disposed on the insulation pattern SP (that is, the protruding portion CL2-T (see FIG. 7C)). The print patterns MIpp may overlap the insulation pattern SP as described in the various embodiments above.

FIG. 12E exemplarily illustrates that a plurality of print patterns MIpp are formed on one of the insulation pattern SP, but a plurality of insulation patterns SP may also be provided, so that the print patterns MIpp are disposed to correspond to the insulation patterns SP, respectively.

FIGS. 12C and 12D exemplarily illustrate that since the removed patterns MIrm are formed to have a trapezoid shape on a cross-section, the print patterns MIpp are formed to have a reversed trapezoid shape on a cross-section. However, an embodiment of the invention is not limited thereto, the removed patterns MIrm may also be formed to have a reversed trapezoid or rectangular shape on a cross-section, and accordingly, the print patterns MIpp may also be formed to have a trapezoid or rectangular shape on a cross-section.

Referring to FIGS. 12F to 12G, the forming of the protruding pattern TP according to an embodiment of the invention may include sintering the print patterns MIpp. The print patterns MIpp according to this embodiment may be formed by the metal ink MI patterned through the cliché CC (see FIG. 12D) being transferred onto the second conductive pattern CL2.

In this embodiment, the print patterns MIpp which is on the preliminary signal pad DP-PDI having un-sintered print patterns, may be sintered using heat or light, and the protruding patterns TP may be formed from the sintered print patterns MIpp. Through the sintering of the print patterns MIpp, the solvent SV (see FIG. 12C) included in the print patterns MIpp may be dried, and the metal nanoparticles NP (see FIG. 12C) may be sintered. FIG. 12F exemplarily illustrates that the print patterns MIpp are sintered using an optical sintering device PCS. Infrared (IR) or ultraviolet (UV) may be used for optical treatment of the un-sintered print patterns. That is, the providing of the protruding conductive pattern may include after the providing of the layer of the metal ink MI, transferring a portion of the layer of the metal ink MI from the blanket BK to a carrier, which provides a print pattern MIpp corresponding to the remaining portion of the layer of the metal ink MI which is on the blanket, transferring the print pattern MIpp from the blanket onto the second conductive pattern CL2 of the preliminary signal pad DP-PDI, the print pattern MIpp overlapping the insulation pattern SP of the preliminary signal pad; DP-PDI and sintering the print pattern MIpp which is on the second conductive pattern CL2 and overlapping the insulation pattern SP of the preliminary signal pad DP-PDI, to form the protruding conductive pattern of the signal pad DP-PD.

The signal pad DP-PD formed from the preliminary signal pad DP-PDI having the print patterns MIpp thereon, through the operations in FIGS. 12A to 12G, may have a planar shape similar with any one among those in FIGS. 10A to 10D. However, an embodiment of the invention is not limited thereto, and in a case where each of the print patterns MIpp is disposed on a corresponding insulation pattern SP in the transferring of the print patterns MIpp in FIG. 12E, the signal pad DP-PD may be formed to have a planar shape, similar with that in FIG. 8A, 11A, or 11B.

According to this embodiment, the display device DD (see FIG. 1) including the signal pad DP-PD, containing the insulation pattern SP and the protruding pattern TP which is disposed on the insulation pattern SP, may be manufactured or provided. In a bonding process, the protruding pattern TP and a bump electrode of an electronic component may come into close contact with each other due to high restoring force of the insulation pattern SP as an impact absorbing member. At the same time, the protruding pattern TP may have a reduced deformation owing to the effect from deformation of the insulation pattern SP in the bonding process. Thus, the protruding pattern TP and the bump electrode may have a stable electrical connection therebetween, and have a reduced bonding resistance therebetween. Therefore, according to this embodiment, it may be possible to manufacture the display device DD (see FIG. 1) including the signal pad DP-PD having improved bonding reliability and electrical connection therebetween.

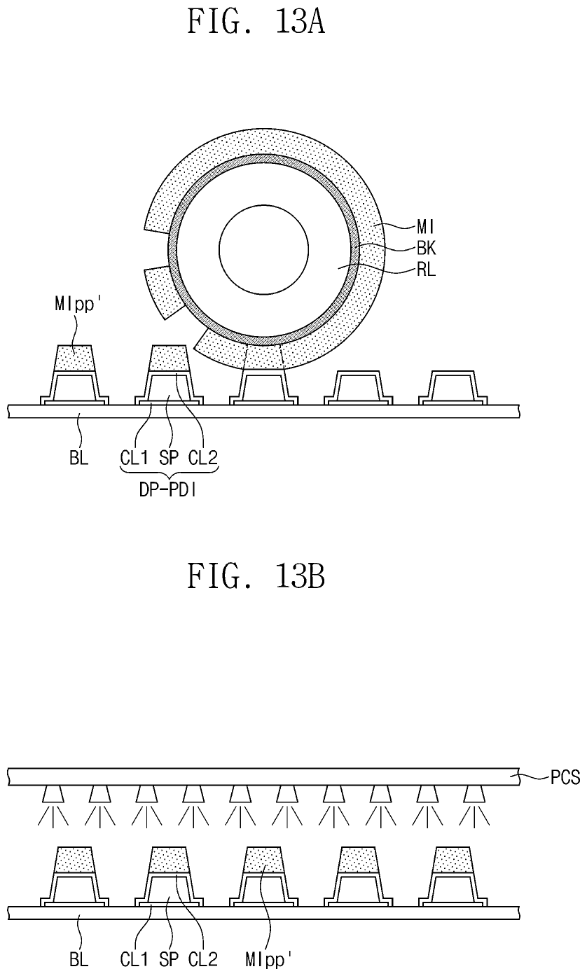

FIGS. 13A and 13B are cross-sectional views illustrating the method of manufacturing or providing of a display device DD according to an embodiment of the invention. Same/similar components as/with the components described with reference to FIGS. 12A to 12G are denoted as the same/similar reference numerals or symbols, and duplicate descriptions will be omitted and differences will be mainly described. In this embodiment, FIG. 13A illustrates an operation which may be performed after the applying of the metal ink MI onto the blanket BK previously described with reference to FIGS. 12B and 12C.

Referring to FIG. 13A, the forming of the protruding pattern TP (see FIG. 7A) according to an embodiment of the invention may include, after the applying of the metal ink MI onto the blanket BK, transferring portions of the metal ink MI from the blanket BK, directly onto a second conductive pattern CL2.

That is, in this embodiment, unlike the embodiment illustrated in FIGS. 12D to 12G, the intermediate transfer of the metal ink MI, which is applied onto the blanket BK, to carrier such as a cliché CC may be omitted, and the metal ink MI applied onto the blanket BK may be directly transferred onto the second conductive pattern CL2. In this embodiment, insulation patterns SP may effectively serve as the cliché CC. Accordingly, direct transfer of the protrusions of the metal ink MI may have the advantage of simplifying the process of providing the display panel DP. As used herein one type of transfer surface useful in the present invention is known in the art as a cliché. Other types of transfer surfaces can also be readily identified and used, such as a carrier providing the various transfer surfaces.

The metal ink MI applied onto the blanket BK may come into contact with the second conductive pattern CL2, which protrudes by the insulation patterns SP, and may thus be transferred onto the second conductive pattern CL2. A portion of the metal ink MI, which is initially applied onto the blanket BK in a single layer, may come into contact with the second conductive pattern CL2 which protrudes by the insulation patterns SP, and may be removed from the blanket BK by adhesion to the material of the second conductive pattern CL2, to remain on the second conductive pattern CL2 as a transferred portion of the layer of the metal ink MI.

In this embodiment, the metal ink MI transferred onto the second conductive pattern CL2 may form print patterns MIpp′ having a shape corresponding to the protruding patterns TP (see FIG. 7A) to be formed later. The print patterns MIpp′ may be disposed respectively corresponding to the insulation patterns SP. That is, the print patterns MIpp′ may be disposed respectively overlapping the insulation patterns SP. In an embodiment, a side surface of each of the print patterns MIpp′ may be substantially aligned with on outer surface of a portion of the second conductive pattern CL2 covering a side surface of the corresponding insulation pattern SP.

FIG. 13A exemplarily illustrates that the print patterns MIpp′ are formed to have a trapezoid shape on a cross-section. However, an embodiment of the invention is not limited thereto, and the print patterns MIpp′ may also be formed to have a reversed trapezoid or rectangular shape.

After this, referring to FIG. 13B, the forming of the protruding pattern TP (see FIG. 7A) according to an embodiment of the invention may include sintering the un-sintered print patterns MIpp′. In this embodiment, the print patterns MIpp′ may be formed by the metal ink MI, which is initially applied onto the blanket BK, being transferred directly onto the second conductive pattern CL2 and being patterned at the same time as the transferring, such as by a bonding force and/or an adhesion between the material of the metal ink MI and the to the material of the second conductive pattern CL2. Through the sintering of the transferred print patterns MIpp′, the protruding patterns TP (see FIG. 7A) may be formed from the sintered transferred print patterns MIpp′. For the description of the sintering of the print patterns, the previous description with reference to FIGS. 12F to 12G will be equally applied. That is, the providing of the protruding conductive pattern may include after the providing of the layer of the metal ink MI, transferring a portion of the layer of the metal ink MI from the blanket BK, directly to the second conductive pattern CL2 of the preliminary signal pad DP-PDI, which provides a print pattern MIpp of the layer of the metal ink MI which is on the preliminary signal pad DP-PDI, the print pattern MIpp overlapping the insulation pattern SP of the preliminary signal pad DP-PDI, and sintering the print pattern MIpp which is on the second conductive pattern CL2 and overlapping the insulation pattern SP of the preliminary signal pad DP-PDI, to form the protruding conductive pattern of the signal pad DP-PD.

The signal pad DP-PD (see FIG. 7A), variously formed or provided through the operations illustrated in FIGS. 12A, 13A, and 13B, may have a cross-sectional shape similar with the shape illustrated in FIG. 8C. The signal pad DP-PD (see FIG. 7A), formed through the operations illustrated in FIGS. 12A, 13A, and 13B, may have a planar shape similar with the shape illustrated in FIG. 8A, 11A, or 11B.

According to an embodiment of the invention, by an insulation pattern SP in a signal pad DP-PD of a display panel DP, an uppermost conductive pattern of the signal pad DP-PD (e.g., at the second conductive layer CL2) may protrude toward an electronic component (e.g., a driving chip DC, a circuit board PB, and the like). Without an anisotropic conductive film, the display panel DP may be bonded to the electronic component, thereby reducing electrical short circuit defects caused by conventional conductive balls of a conventional bonding film. As bonding pressure is reduced to electrically connect the electronic component to the display panel DP at the signal pad DP-PD thereof, physical damages to the display panel DP and/or the electronic component, which occur during a bonding process, may be reduced.

According to an embodiment of the invention, the signal pad DP-PD may include a protruding pattern TP disposed on the insulation pattern SP. Through high restoring force of the insulation pattern SP, the protruding pattern TP and a bump electrode of the electronic component may come into close contact with each other. At the same time, the protruding pattern TP and the bump electrode may have a stable electrical connection to each other through physical contact therebetween. It may be possible to provide a display device DD having improved bonding reliability and electrical connection between an external (electronic) component and a pad electrode of a display panel DP.

According to an embodiment of the invention, it may be possible to manufacture or provide a display device DD including the signal pad DP_PD capable of improving bonding reliability.

Although the embodiments of the invention have been described, it is understood that the invention should not be limited to these embodiments but various changes and modifications can be made by one ordinary skilled in the art within the spirit and scope of the invention as hereinafter claimed. Therefore, the technical scope of the invention should not be limited to the contents described in the detailed description of the specification, but should be defined by the claims.

What is claimed is:

1. A display device comprising:
a display module including:
a pixel;
a signal line electrically connected to the pixel and defining an end portion furthest from the pixel; and
a signal pad electrically connected to the signal line and to which an electrical signal is provided from an electronic component external to the display module, the signal pad including:
a first conductive pattern at which the signal pad is electrically connected to the end portion of the signal line,
a second conductive pattern facing the first conductive pattern and electrically connected to the first conductive pattern,
an insulation pattern between the first conductive pattern and the second conductive pattern which face each other, and
a protruding conductive pattern at which the signal pad is electrically connected to the electronic component, the protruding conductive pattern protruding from the second conductive pattern and overlapping the insulation pattern.

2. The display device of claim 1, wherein
the protruding conductive pattern comprises metal, and
the insulation pattern comprises polymer.

3. The display device of claim 2, wherein the protruding conductive pattern comprises copper or silver.

4. The display device of claim 1, wherein within the signal pad:
the second conductive pattern comprises a protruding portion which is extended along the insulation pattern and protrudes from the first conductive pattern, and
the protruding conductive pattern protrudes from the protruding portion of the second conductive pattern.

5. The display device of claim 4, wherein
the first conductive pattern extends further than a side surface of the insulation pattern to define an upper surface of the first conductive pattern which is exposed outside of the insulation pattern, and
the second conductive pattern further comprises:
the protruding portion in contact with the side surface and an upper surface of the insulation pattern, and
an extended portion which extends from the protruding portion and further from the insulation pattern, the extended portion contacting the upper surface of the first conductive pattern.

6. The display device of claim 1, wherein an entirety of the protruding conductive pattern of the signal pad is overlapped by the insulation pattern.

7. The display device of claim 1, wherein
each of the protruding conductive pattern and the second conductive pattern has a side surface, and
the side surface of the protruding conductive pattern is aligned with the side surface of the second conductive pattern.

8. The display device of claim 1, wherein the protruding conductive pattern comprises one of a trapezoid cross-sectional shape, a reversed trapezoid cross-sectional shape, and a rectilinear cross-sectional shape.

9. The display device of claim 1, wherein
the second conductive pattern comprises:
a first layer, a second layer and a third layer stacked in sequence in a direction from the insulation pattern to the protruding conductive pattern,
the second layer thicker than each of the first layer and the third layer,
the second layer which is thicker having a higher electrical conductivity than that of each of the first layer and the third layer, and
a portion of the second layer exposed outside of the third layer, and
the protruding conductive pattern contacts the portion of the second layer which is exposed outside of the third layer.

10. The display device of claim 9, wherein
the second conductive pattern further comprises:
the first layer, the second layer, the third layer and an oxide film stacked in sequence in the direction from the insulation pattern to the protruding conductive pattern, and
the portion of the second layer exposed outside of both the oxide film and the third layer, and
the protruding conductive pattern contacts the portion of the second layer which is exposed outside of both the oxide film and the third layer.

11. The display device of claim 1, wherein within the signal pad, the protruding conductive pattern is provided in plural including protruding conductive patterns spaced apart from each other along the insulation pattern.

12. The display device of claim 1, wherein within the signal pad:
the insulation pattern and the protruding conductive pattern are each provided in plural, and
the protruding conductive patterns respectively overlap the insulation patterns.

13. The display device of claim 1, wherein
the display module further comprises a pad insulation layer between the first conductive pattern of the signal pad and the end portion of the signal line, and
within the signal pad:
a contact hole is defined in the pad insulation layer which exposes the end portion of the signal line to outside the pad insulation layer and is spaced apart from the insulation pattern in a direction along the signal pad, and
the first conductive pattern contacts the end portion of the signal line through the contact hole which is defined in the pad insulation layer.

14. The display device of claim 13, wherein within the signal pad:
the insulation pattern and the contact hole are each provided in plural, and
the insulation patterns are between adjacent contact holes among the contact holes.

15. The display device of claim 1, wherein the pixel comprises:
a light-emitting element;
a transistor electrically connected to the light-emitting element, the transistor including a semiconductor pattern and a gate which overlaps the semiconductor pattern;
an upper electrode on the gate of the transistor; and
connection electrodes electrically connected to the transistor, the connection electrodes respectively on different layers of the pixel,
the end portion of the signal line in a same layer as the gate of the transistor or the upper electrode,
the first conductive pattern in a same layer as that of a first connection electrode among the connection electrodes, and
the second conductive pattern in a same layer as a second connection electrode different from the first connection electrode among the connection electrodes.

16. The display device of claim 1, wherein:
the electronic component includes a bump electrode at which the electronic component is electrically connected to the signal pad of the display module; and
an adhesive layer which is between the display module and the electronic component, bonds the display module to the electronic component and within which the protruding conductive pattern is in contact with the bump electrode to electrically connect the electronic component to the display module.

17. A method of providing a signal pad of a display device, the method comprising:
providing a preliminary signal pad including:
a first conductive pattern connected to a signal line of a display module of the display device,
a second conductive pattern on the first conductive pattern, and
an insulation pattern between the first conductive pattern and the second conductive pattern; and
providing a protruding conductive pattern on the preliminary signal pad, to form the signal pad of the display module at which the display module of the display device is connected to an electronic component of the display device,
wherein the providing of the protruding conductive pattern on the preliminary signal pad comprises a reverse offset printing process.

18. The method of claim 17, wherein the providing of the protruding conductive pattern further comprises providing a layer of metal ink including a solvent and metal nanoparticles, onto a blanket movable relative to the preliminary signal pad.

19. The method of claim 18, wherein the providing of the protruding conductive pattern further comprises after the providing of the layer of the metal ink:
transferring a portion of the layer of the metal ink from the blanket to a carrier, which provides a print pattern corresponding to the remaining portion of the layer of the metal ink which is on the blanket;
transferring the print pattern from the blanket onto the second conductive pattern of the preliminary signal pad, the print pattern overlapping the insulation pattern of the preliminary signal pad; and
sintering the print pattern which is on the second conductive pattern and overlapping the insulation pattern of the preliminary signal pad, to form the protruding conductive pattern of the signal pad.

20. The method of claim 18, wherein the providing of the protruding conductive pattern further comprises after the providing of the layer of the metal ink:
transferring a portion of the layer of the metal ink from the blanket, directly to the second conductive pattern of the preliminary signal pad, which provides a print pattern of the layer of the metal ink which is on the preliminary signal pad, the print pattern overlapping the insulation pattern of the preliminary signal pad, and
sintering the print pattern which is on the second conductive pattern and overlapping the insulation pattern of the preliminary signal pad, to form the protruding conductive pattern of the signal pad.
